(19) United States
(12) Patent Application Publication
(10) Pub. No.: US 2010/0176381 A1
(43) Pub. Date: Jul. 15, 2010

(54) SEMICONDUCTOR DEVICE AND DISPLAY DEVICE

(75) Inventors: Iwao Yagi, Kanagawa (JP); Akira Yumoto, Kanagawa (JP)

Correspondence Address: SONNENSCHEIN NATH & ROSENTHAL LLP, P.O. BOX 061080, WACKER DRIVE STATION, WILLIS TOWER, CHICAGO, IL, 60606-1080, US

(73) Assignee: SONY CORPORATION, Tokyo (JP)

(21) Appl. No.: 12/522,053

(22) PCT Filed: Dec. 26, 2007
(86) PCT No.: PCT/JP2007/074983

§ 371 Date: Mar. 19, 2010

(30) Foreign Application Priority Data
Jan. 10, 2007 (JP) 2007-001930

(51) Int. Cl. H01L 51/10; H01L 33/02

(52) U.S. Cl. 257/40; 257/59; 257/E33.053; 257/E51.006

(57) ABSTRACT

It is an object to provide a display device in which an operational characteristic in a bottom gate type organic semiconductor thin film transistor can be maintained to a stable characteristic without receiving an influence of an electrode provided on an upper layer thereof, and a display with a high reliability can be realized by using this as a driver element. A bottom gate type thin film transistor Tr provided on a substrate 1 and a pixel electrode a provided on an upper part of the thin film transistor Tr via a protection film 11 and an inter-layer insulating film 15 are provided, and between the thin film transistor Tr and the pixel electrode a, a conductive shield layer 13a is arranged while an insulation property is maintained between these.

### TECHNICAL FIELD

The present invention relates to a semiconductor device and a display device, in particular, a semiconductor device using an organic semiconductor thin film, and a display device using this semiconductor device.

### BACKGROUND ART

A thin film transistor (thin film transistor: TFT) is widely used as a switching element for a pixel electrode in a flat panel type display device of an active matrix drive. Among such thin film transistors, an organic semiconductor thin film transistor using an organic semiconductor thin film for a channel layer enables coat film formation of the channel layer (organic semiconductor thin film) without using a vacuum processing device. For this reason, realization of a lower cost is advantageous as compared with an inorganic thin film transistor using a silicon thin film for the channel layer.

In the above-mentioned display device, a configuration of a drive substrate on which the organic semiconductor thin film transistor is provided is as follows. That is, in a display region on the insulative substrate, scanning lines and signal lines are arranged crisscross while maintaining the insulation property. Then, at a crossing point of these wirings, for example, a bottom gate type organic semiconductor thin film transistor is provided. Also, contact holes reaching the respective organic semiconductor thin film transistors are provided on an insulating film covering the organic semiconductor thin film transistor, and on this insulating film, pixel electrodes are disposed and formed which are connected to the respective organic semiconductor thin film transistors via the contact holes (for the above, for example, Japanese Unexamined Patent Application Publication No. 2006-86502 (in particular, see FIGS. 1 to 3 and related description parts).

Incidentally, as to the configuration of the organic semiconductor thin film transistor, from the viewpoint of not only ease of a manufacturing procedure but also transport characterization of carriers, the bottom gate type is considered to be advantageous. To elaborate, the organic semiconductor thin film formed on the substrate has higher flatness on a lower face side as compared with an upper face side, and for this reason, it is considered that the transport characterization of carriers becomes satisfactory in the bottom gate type where a channel section is formed on the lower face side.

However, in a semiconductor device and a display device using the bottom gate type organic semiconductor thin film transistor, the electrode and wiring on the insulating film covering the organic semiconductor thin film transistor are arranged at a distance extremely close to the organic semiconductor thin film which constitutes the channel section. For this reason, due to an influence of a potential applied to the electrode, the wiring, and the like, a problem occurs that a transistor characteristic of the organic semiconductor thin film transistor tends to degrade.

For example, in the display device, the pixel electrode is arranged through lamination on an upper part of the organic semiconductor thin film transistor, and the organic semiconductor thin film transistor thus receives potential modulation caused by the potential applied to the pixel electrode. Due to such potential modulation, drive of the pixel electrode becomes unstable, and a reliability of display is degraded. Also, an amplitude of an operation voltage for switching the organic semiconductor thin film transistor is increased, and an increase in power consumption is caused.

Also, in particular, when the display device is an organic EL (electroluminescence) display device using an organic electroluminescence element, a common electrode opposing the pixel electrode may be arranged at a position close to the upper part of the organic semiconductor thin film transistor. Even in such a case, the organic semiconductor thin film transistor receives the potential modulation caused by the potential applied to the common electrode, and a similar problem occurs.

In view of the above, according to the present invention, it is an object to provide a semiconductor device capable of maintaining an operating characteristic in a bottom gate type organic semiconductor thin film transistor to a stable characteristic without receiving an influence of an electrode provided on an upper layer thereof and to provide a display device capable of carrying out display with a high reliability by using the semiconductor device for a drive substrate.

### DISCLOSURE OF INVENTION

A semiconductor device according to the present invention for achieving such an object is a semiconductor device including a bottom gate type thin film transistor provided on a substrate and an electrode provided on an upper part of the thin film transistor via an insulating film, characterized in that, in particular, between the thin film transistor and the electrode, a conductive shield layer is arranged while an insulation property between these is maintained.

Also, the semiconductor device according to the present invention is a display device using the above-mentioned semiconductor device as a drive substrate, and the electrode provided on the upper part of the thin film transistor is a pixel electrode connected to the thin film transistor or a common electrode commonly arranged opposite to a plurality of thin film transistors.

In the semiconductor device or the display device having such a configuration, as the conductive shield layer is arranged between the bottom gate type thin film transistor and the electrode arranged on the upper part thereof, a potential applied to the electrode is prevented from exerting an influence on a channel layer of the bottom gate type thin film transistor.

As described above, according to the present invention, with the shielding layer, as the potential applied to the electrode can be prevented from exerting the influence on the channel layer of the bottom gate type thin film transistor, an operational characteristic in the bottom gate type thin film transistor can be maintained to a stable characteristic without receiving the influence of the electrode provided on the upper layer thereof. Then, in the display device using the bottom gate type thin film transistor for driving the pixel electrode, it is possible to carry out display with a high reliability.

### BRIEF DESCRIPTION OF DRAWINGS

FIG. 1 is a schematic circuit configuration diagram for describing a configuration example of a liquid crystal display device to which the present invention is applied.

FIG. 2 is a cross sectional view of one pixel for describing a characterizing part of a liquid crystal display device according to a first embodiment.

FIG. 3 is a plane view of four pixels on a drive substrate side for describing the characterizing part of the liquid crystal display device according to the first embodiment.

FIG. 4 is a cross sectional view of one pixel for describing a characterizing part of a liquid crystal display device according to a second embodiment.

FIG. 5 is a plane view of four pixels on a drive substrate side for describing the characterizing part of the liquid crystal display device according to the second embodiment.

FIG. 6 is a cross sectional view of one pixel for describing a characterizing part of a liquid crystal display device according to a third embodiment.

FIG. 7 is a plane view of four pixels on a drive substrate side for describing the characterizing part of the liquid crystal display device according to the third embodiment.

FIG. 8 is a schematic circuit configuration diagram for describing a configuration example of an organic EL display device to which the present invention is applied.

FIG. 9 is a cross sectional view of one pixel for describing a characterizing part of an organic EL display device according to a fourth embodiment.

FIG. 10 is a substantial part plane view of four pixels for describing the characterizing part of the organic EL display device according to the fourth embodiment.

FIG. 11 is a substantial part plane view of four pixels for describing a characterizing part of an organic EL display device according to a fifth embodiment.

FIG. 12 is a substantial part plane view of four pixels for describing a characterizing part of an organic EL display device according to a sixth embodiment.

FIG. 13 is a cross sectional view of one pixel for describing a characterizing part of an organic EL display device according to a seventh embodiment.

FIG. 14 is a substantial part plane view of four pixels for describing the characterizing part of the organic EL display device according to the seventh embodiment.

FIG. 15 is a substantial part plane view of four pixels for describing a characterizing part of an organic EL display device according to an eighth embodiment.

FIG. 16 is a cross sectional view of one pixel for describing a characterizing part of an organic EL display device according to a ninth embodiment.

FIG. 17 is a substantial part plane view of four pixels for describing the characterizing part of the organic EL display device according to the ninth embodiment.

FIG. 18 is a substantial part plane view of four pixels for describing a characterizing part of an organic EL display device according to a tenth embodiment.

FIG. 19 is a cross sectional view of one pixel for describing a characterizing part of an organic EL display device according to an eleventh embodiment.

FIG. 20 is a substantial part plane view of four pixels for describing the characterizing part of the organic EL display device according to the eleventh embodiment.

FIG. 21 is a substantial part plane view of four pixels for describing a characterizing part of an organic EL display device according to a twelfth embodiment.

FIG. 22 is a substantial part plane view of four pixels for describing a characterizing part of an organic EL display device according to a thirteenth embodiment.

FIG. 23 is a cross sectional view of one pixel for describing a characterizing part of an organic EL display device according to a fourteenth embodiment.

FIG. 24 is a substantial part plane view of four pixels for describing the characterizing part of the organic EL display device according to the fourteenth embodiment.

FIG. 25 is a cross sectional view of one pixel for describing a characterizing part of an organic EL display device according to a fifteenth embodiment.

FIG. 26 is a substantial part plane view of four pixels for describing the characterizing part of the organic EL display device according to the fifteenth embodiment.

FIG. 27 is a cross sectional view of one pixel for describing a characterizing part of an electrophoretic display device according to a sixteenth embodiment.

FIG. 28 is a cross sectional view which describes a seventeenth embodiment.

FIG. 29 is a flow chart which describes an eighteenth embodiment.

### BEST MODES FOR CARRYING OUT THE INVENTION

Hereinafter, embodiments of a semiconductor device and a display device according to the present invention will be described in detail on the basis of the drawings. It should be noted that according to the respective embodiments, a description will be given of a configuration of the display device in which the semiconductor device of the present invention is used for a drive substrate.

### First Embodiment

According to a first embodiment, an embodiment will be described in which the present invention is applied to an active matrix system liquid crystal device.

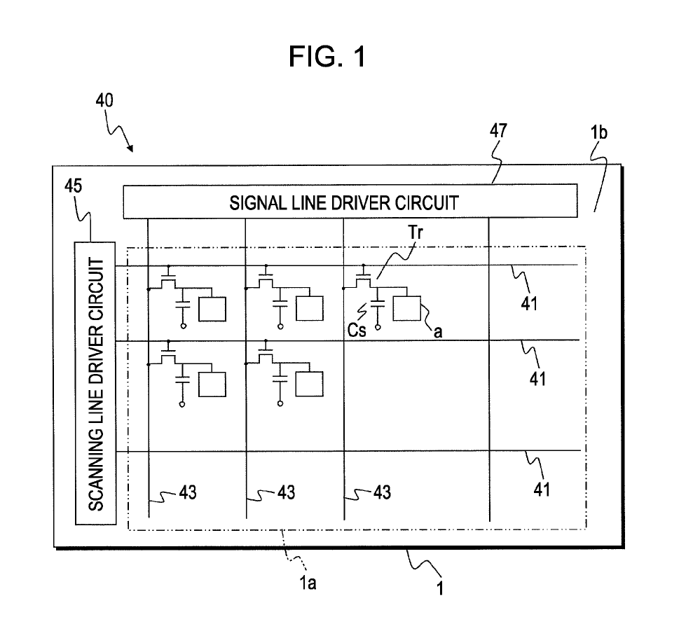

FIG. 1 is a schematic circuit configuration diagram for describing a configuration example of a liquid crystal display device to which the present invention is applied. As shown in this drawing, a display region 1a and a peripheral region 1b thereof are set on a substrate 1 on a liquid crystal display device 40. On the display region 1a, a plurality of scanning lines 41 and a plurality of signal lines are arranged lengthwise and crosswise, and pixel array sections are constructed in which one pixel is provided corresponding to the respective cross sections. Also, on the peripheral region 1b, a scanning line driver circuit 45 for scanning and driving the scanning lines 41 and a signal line driver circuit 47 for supplying a video signal in accordance with luminance information (that is, an input signal) to the signal lines 43 are arranged.

The pixel circuit provided to the respective cross sections of the scanning lines 41 and the signal lines 43 is composed, for example, of a thin film transistor Tr, a holding capacity Cs, and a pixel electrode a. Then, through a drive by the scanning line driver circuit 45, the video signal written from the signal line 43 via the thin film transistor Tr is held in the holding capacity Cs, a voltage in accordance with the held signal amount is supplied to the pixel electrode a, and liquid crystal molecules constituting a liquid crystal layer are inclined in accordance with this voltage to control transmission of display light.

It should be noted that the above-mentioned configuration of the pixel circuit is merely an example, and the pixel circuit may also be constructed by providing a capacitance element inside the pixel circuit when necessary or further providing a plurality of transistors. Also, on the peripheral region 1b, a necessary driver circuit is added in accordance with a change in the pixel circuit.

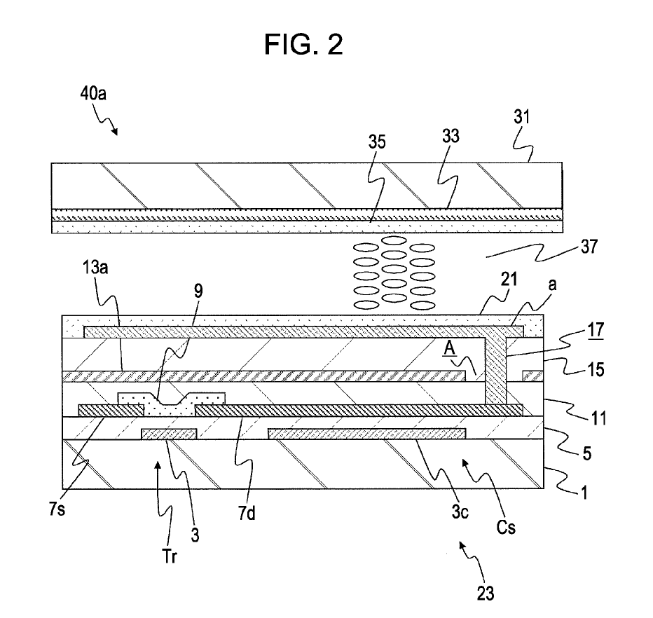

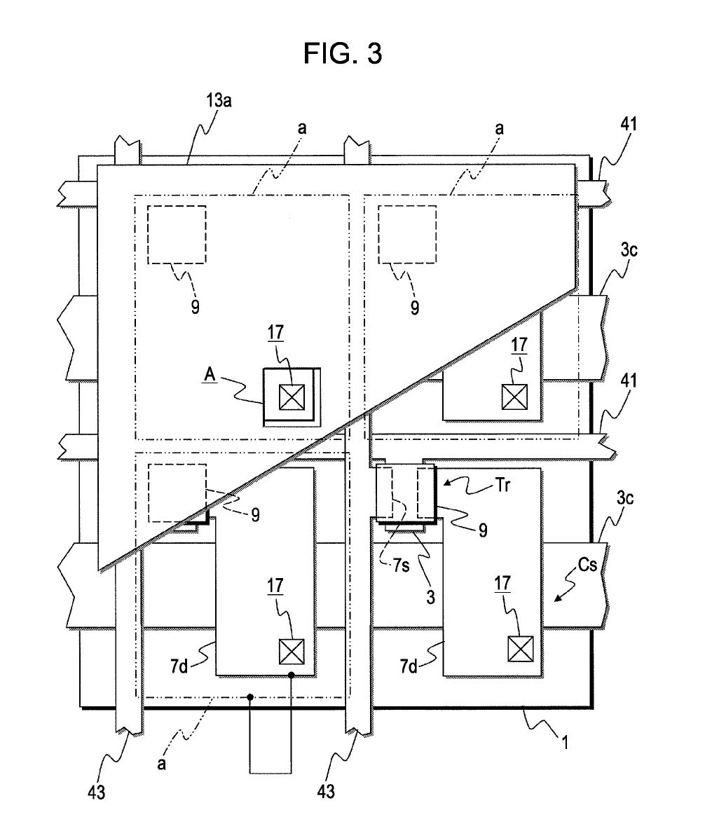

FIG. 2 shows a cross sectional view of one pixel for describing a characterizing part of a liquid crystal display device 40a according to the present first embodiment. Also, FIG. 3 shows a plane view of four pixels on a drive substrate side for describing the characterizing part of the liquid crystal display device 40a according to the present first embodiment. It should be noted that a part of the plane view is cut off for the sake of description, and further, representation of a film composed of an insulative material which covers the entirety is omitted from the drawing. It should be noted that the same symbols are assigned to the same components as those of FIG. 1.

As shown in these drawings, in the respective pixels of the liquid crystal display device 40a according to the first embodiment, the bottom gate type thin film transistor Tr is provided in which a gate electrode 3, a gate insulating film 5, a source electrode 7s and a drain electrode 7d, and a channel layer 9 composed of an organic semiconductor material (hereinafter described as organic channel layer) are laminated on the substrate 1 in this order. Also, a lower part electrode 3c of the holding capacity Cs is provided on the same layer as the gate electrode 3, and further, on the same layer as the source electrode 7s and the drain electrode 7d, the upper part electrode of the holding capacity Cs provided extending from the drain electrode 7d is provided. Furthermore, as shown in the plane view, the gate electrode 3 is provided extending from the scanning line 41 composed on the same layer, the source electrode 7s is provided extending from the signal line 43 composed on the same layer, and the lower part electrode 3c of the holding capacity Cs is wired as a common electrode for a plurality of pixels.

On an insulative protection film 11 covering the thin film transistor Tr and the holding capacity Cs described above, a conductive shield layer 13a which is characteristic to the present first embodiment is provided. This shield layer 13a is set to be provided in a state of at least covering a top of the organic channel layer 9, and in particular, according to the present first embodiment, provided in a state of covering the entire surface of the display region. However, on this shield layer 13a, an opening section A facing the upper electrode of the holding capacity Cs is set to be provided for each pixel.

The above-mentioned shield layer 13a is drawn from the display region to the peripheral region to be wired and has an independently potential controllable configuration with respect to other electrodes and wirings.

On an inter-layer insulating film 15 covering the above-mentioned shield layer 13a, the pixel electrode a (represented in the plane view by the two-dot chain line) is provided. The respective pixel electrodes a are connected via a contact section 17 provided on an inner side of the opening section A to the upper electrode of the holding capacity Cs (the drain electrode 7d).

Then, in a state of covering these pixel electrodes a, for example, an oriented film 21 subjected to a surface rubbing processing is provided, and a drive substrate 23 is constructed.

The respective layers constructing the drive substrate 23 having the above-mentioned configuration can be constructed by using a general material, and this is not particularly limited. Also, as long as functions are not impaired, the respective layers may have a multilayer construction composed of a plurality of materials. These examples include introduction of an adhesive layer into an electrode lower part for securing adhesion property with a ground, introduction of an etch stopper layer onto the electrode, introduction of a laminate layer metal construction for securing gas barrier property and securing ductility, and the like. Representative examples of the respective materials are shown as follows.

The gate electrode 3 . . . aluminum, gold, a laminated film of gold/chrome, silver, palladium, and further, a laminate film of these.

The gate insulating film 5 . . . oxide silicon, silicon nitride, polyvinyl phenol, polymethyl methacrylate (PMMA), etc.

The source and drain electrodes 7s and 7d . . . gold, a laminated film of gold/chrome, silver, platinum, palladium, and further, a laminate film of these.

The organic channel layer 9 . . . pentacene, thiophene oligomer such as xythiophene, polythiophene, etc.

The protection film 11 . . . silicon nitride, oxide silicon, poly-para-xylylene, polyvinyl alcohol, etc.

The shield layer 13a . . . gold, a laminated film of gold/chrome, silver, aluminum, and further, a laminate film of these.

The inter-layer insulating film 15 . . . silicon nitride, Poly-para-Xylylene, acrylic resin such as PMMA, polyvinyl alcohol, etc.

The pixel electrode a . . . aluminum, gold, a laminated film of gold/chrome, silver, palladium, and a laminate film of these.

Also, as to the methods for formation and process on the respective layers, a known technology can be widely used. For example, a general film formation method such as vacuum deposition, sputtering, or CVD, a film formation method using liquid solution such as spin coat or cap coat, a pattern screen printing, or inkjet printing, a pattern transfer method such as a photolithography method, an electron lithography method, a micro printing method, or a nanoimprint method, and an etching and pattern formation technology such as a wet etching method, a dry etching method, or a liftoff can be widely combined. When combining these, it is of course possible to also use a general semiconductor formation technology such as necessary heating or washing.

It should be noted that in a case where the shield layer 13a is provided with a light interception function, a tolerability of the organic channel layer 9 is improved with respect to a processing using light such as a lithography performed in a procedure after formation of the shield layer 13a.

Also, as to the thickness of the respective layers too, as long as the function is not impaired, this is not limited. For example, the gate electrode 3, the source and drain electrodes 7s and 7d, the shield layer 13a, the pixel electrode a, the gate insulating film 5, and the organic channel layer 9 are equal to or smaller than 1 μm, more preferably, equal to or smaller than 500 nm. Also, the protection film 11 and the inter-layer insulating film 15 are equal to or smaller than 5 μl, more preferably, equal to or smaller than 3 μm.

Furthermore, as to a shape and size of a connecting hole constituting the contact section 17 between the pixel electrode a and the holding capacity Cs too, this is not limited. In this case, a connecting hole of the inter-layer insulating film 15 and a connecting hole of the protection film 11 are not necessarily matched in the shape and size with each other, and for example, a configuration that is [an opening shape of the inter-layer insulating film 15>an opening shape of the protection film 11] and a configuration that is [an opening shape of the inter-layer insulating film<an opening shape of the protection film] are also included.

Also, as to the substrate 1 too, in a range where heat resistance exists with respect to a heat history in the manufacturing processing, the material and the board thickness are not particularly limited. For example, a hard material such as glass and a soft plastic material such as polyether sulfone (PES) or polyethylene naphthalate (PEN) can also be used. Also, when a construction of the lower layer than the gate electrode 3 is considered as the substrate 1, a protection film or a buffer layer may exist on the above-mentioned glass or plastic. For example, a case in which a silicon nitride (SiNx) thin film is attached on the glass substrate for the purpose of gas barrier or a configuration of providing SiNx, an acrylic thin film or the like for surface protection and planarization on the plastic film may also be adopted.

Also, the fabrication procedure of the drive substrate 23 is not particularly limited. For example, a step of forming the connecting hole constituting the contact section 17 between the pixel electrode a and the holding capacity Cs in the protection film 11 may be any one of before the shield layer 13a is formed, after the shield layer 13a is formed, and further at the same time as forming the connecting hole in the inter-layer insulating film 15.

In the above-mentioned drive substrate 23, as being composed of a reflecting material, the pixel electrode a is used as a back face board in the liquid crystal display device 40a.

On the above-mentioned oriented film 21 side of the drive substrate 23, an opposite substrate 31 is arranged. This opposite substrate 31 is composed of a transparent substrate such as the glass substrate, and an opposite electrode 33 common for all the pixels towards the drive substrate 23 side and an oriented film 35 are arranged in this order. It should be noted that a general composite material for the liquid crystal display device may also be applied for such a composite material on the opposite substrate 31 side.

Then, a spacer whose representation in the drawing is omitted is sandwiched between the above-mentioned drive substrate 23 and the opposite substrate 31, and further a liquid crystal layer 37 is filled and sealed to construct the liquid crystal display device 40a. It should be noted that although not apparently represented in the drawing, for example, a portion having a function of suppressing reflection of outside light such as an antireflection film may exist on an outer face of the opposite substrate 31, and in this case, after the portion having the relevant function is formed, an assembly step may be carried out in which the spacer is sandwiched between the drive substrate 23 and the opposite substrate 31 to fill and seal the liquid crystal layer 37. Also, on the opposite substrate 31 side, when necessary, a color filter layer may also be provided.

In the above-mentioned liquid crystal display device (semiconductor device) 40a having the configuration according to the first embodiment, as the conductive shield layer 13a is arranged between the bottom gate type thin film transistor Tr and the pixel electrode a arranged on the upper part, the potential applied to the pixel electrode a is prevented from affecting the organic channel layer 9 of the thin film transistor Tr. For this reason, the operating characteristics in the bottom gate type thin film transistor Tr can be maintained to the stable characteristics without being affected by the voltage applied to the pixel electrode a. As a result, the stabilization of the voltage applied to the pixel electrode a is realized, and it is therefore possible to carry out the display with a high reliability.

Also, with the configuration in which almost the entire surface of the display region is covered by the shield layer 13a, the shield layer 13a can show the highest gas barrier capability with respect to the organic channel layer 9. For this reason, the degradation of the organic channel layer 9 is prevented, and it is possible to improve the reliability of the thin film transistor Tr.

Furthermore, as the potential at the shield layer 13a arranged opposite to the organic channel layer 9 can be independently controlled with respect to other electrodes, an operational characteristic of the thin film transistor Tr can also be controlled by the potential applied to this shield layer 13a. As a specific example, an arbitrary potential is added to the shield layer 13a (for example, 0 V) to interrupt the potential at the pixel electrode a, and the stable operation of the thin film transistor Tr is realized to contribute to the power saving. Also, in the operating voltage, an OFF current and an ON current of the thin film transistor Tr can be adjusted, and by using this, it is therefore possible to carry out the control on the contrast upon display.

It should be noted that according to the present first embodiment, the configuration may suffice in which the shield layer 13a provided in a state of at least covering the organic channel layer 9 of the thin film transistor Tr can independently carry out the potential control, and the shield layer 13a may also be subjected to patterning. For example, the shield layer 13a may be subjected to the patterning for each of the pixels taking out light of the same color. In a case where the respective pixels for red, green, and blue are disposed along the signal lines 43, the shield layer 13a may be subjected to the patterning along the signal lines 43. Then, with the configuration of controlling the potential applied to the shield layer 13a for each of the respective colors, it is possible to carry out the hue adjustment.

### Second Embodiment

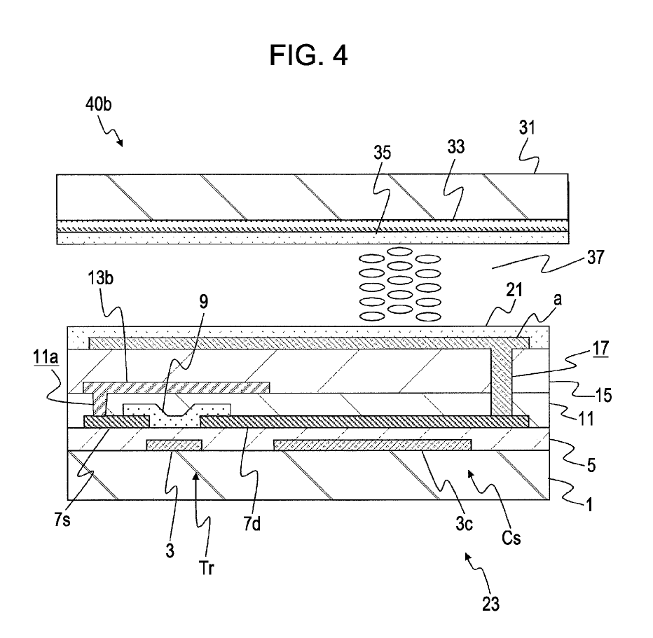

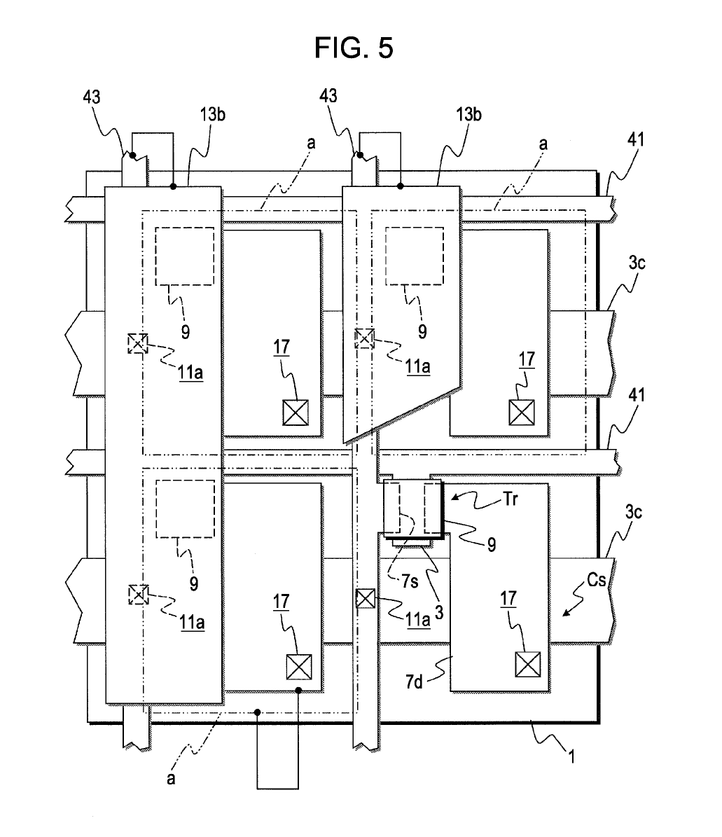

FIG. 4 shows a cross sectional view of one pixel for describing a characterizing part of a liquid crystal display device 40b according to the present second embodiment. Also, FIG. 5 shows a plane view of four pixels on a drive substrate side for describing the characterizing part of the liquid crystal display device 40b according to the present second embodiment. It should be noted that a part of the plane view is cut off for the sake of description, and further, representation of a film composed of an insulative material which covers the entirety is omitted from the drawing. Also, a schematic circuit configuration for describing a configuration example of the liquid crystal display device may be similar to the configuration described according to the first embodiment by using FIG. 1.

A difference between the liquid crystal display device 40b according to the second embodiment shown in these drawings and the liquid crystal display device according to the first embodiment described by using FIGS. 2 and 3 resides in a configuration of a shield layer 13b, and other configurations are set to be similar to one another.

That is, it is characterized in that the shield layer 13b in the liquid crystal display device 40b according to the second embodiment is connected via a contact section 11a composed of the connecting hole provided in the protection film 11 and a conductive material filling the inside thereof to the source electrode 7s. However, it suffices that this shield layer 13b is connected to the source electrode 7s, and in consideration of the layout of the contact section 11a, it may also be connected to a part of the signal line 43 provided extending from the source electrode 7s (see the plane view). Also, the respective shield layers 13b covering the plurality of thin film transistors Tr in a state of sharing the one signal line 43 may be connected to the signal line 43 at least at one position, and the connecting position may also be in the peripheral region.

The respective shield layers 13b are divided for each part covering the thin film transistors Tr which share the one signal line 43 and are set to be subjected to the patterning along the signal line 43 in a state covering at least the organic channel layer 9 of the thin film transistors Tr. It should be noted that it suffices that the respective shield layers 13b are connected to the respective source electrodes 7s or the signal line 43 on an extent thereof and thus may also be subjected to the patterning for each pixel.

Even in the above-mentioned liquid crystal display device (semiconductor device) 40b having the configuration according to the second embodiment, the conductive shield layer 13b is arranged between the bottom gate type thin film transistor Tr and the pixel electrode a arranged on the upper part. For this reason, similarly as in the first embodiment, the operational characteristic in the bottom gate type thin film transistor Tr can be maintained to the stable characteristic. Also, the stabilization of the voltage applied to the pixel electrode a is realized, and it is therefore possible to carry out the display with a high reliability.

### Third Embodiment

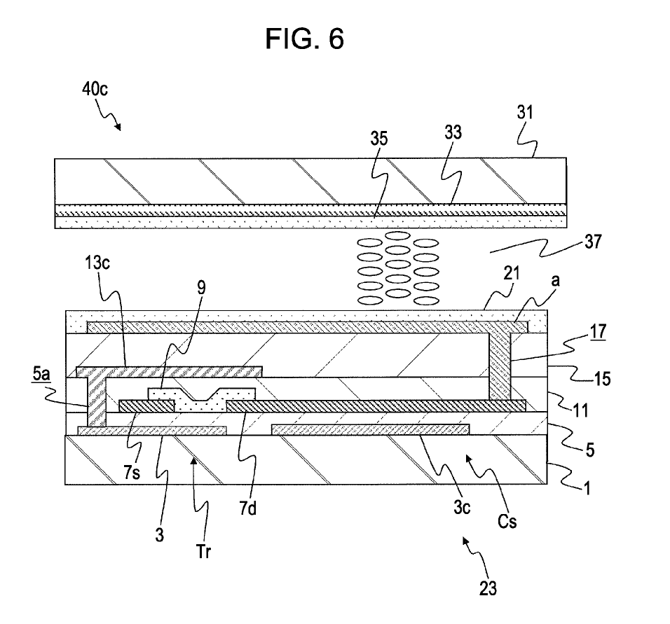

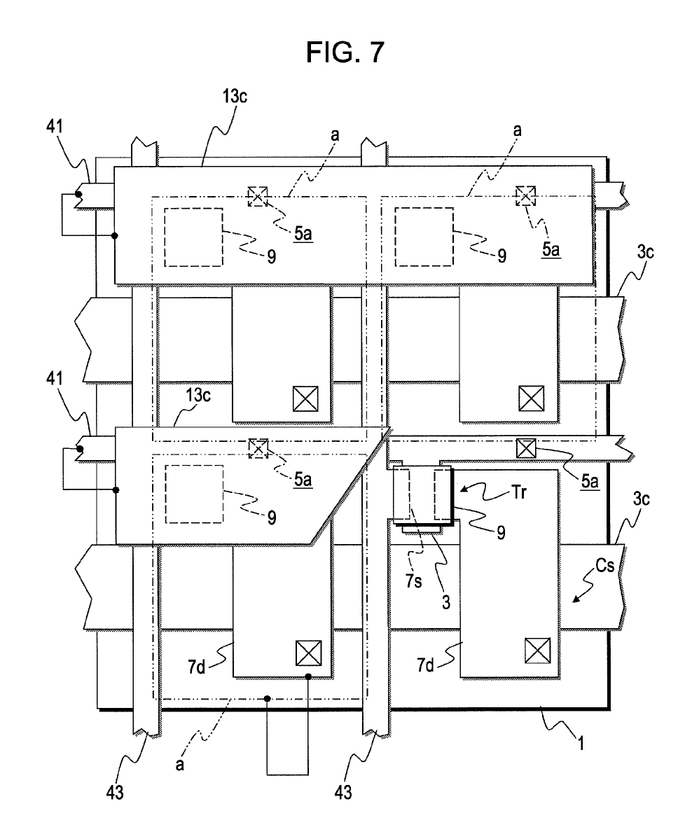

FIG. 6 shows a cross sectional view of one pixel for describing a characterizing part of a liquid crystal display device 40c according to the present third embodiment. Also, FIG. 7 shows a plane view of four pixels on a drive substrate side for describing the characterizing part of the liquid crystal display device 40c according to the present third embodiment. It should be noted that a part of the plane view is cut off for the sake of description, and further, representation of a film composed of an insulative material which covers the entirety is omitted from the drawing. Also, a schematic circuit configuration for describing a configuration example of the liquid crystal display device may be similar to the configuration described according to the first embodiment by using FIG. 1.

A difference between the liquid crystal display device 40c according to the third embodiment shown in these drawings and the liquid crystal display device according to the first embodiment and the second embodiment described by using FIGS. 2 to 5 resides in a configuration of a shield layer 13c, and the other configurations are set to be similar to one another.

That is, it is characterized in that the shield layer 13c in the liquid crystal display device 40c according to the third embodiment is connected via a contact section 5a composed of the connecting holes provided in the protection film 11 and the gate insulating film 5 and a conductive material filling the inside thereof to the gate electrode 3. However, it suffices that this shield layer 13c is connected to the gate electrode 3, and in consideration of the layout of the contact section 5a, may also be connected at a part of the scanning line 41 arranged extending from the gate electrode 3 (see the plane view). Also, it suffices that the respective shield layers 13c covering the plurality of thin film transistors Tr in a state of sharing one scanning line 41 is connected to the scanning line 41 at least one position, and the connecting position may also be in the peripheral region.

The respective shield layers 13c are divided for each part covering the thin film transistors Tr which share one scanning line 41 and set to be subjected to the patterning along the scanning line 41 in a state of covering at least the organic channel layer 9 of the thin film transistor Tr. It should be noted that it suffices that the respective shield layers 13c are connected to the respective gate electrodes 3 or the scanning line 41 on an extent thereof and thus may also be subjected to the patterning for each pixel.

Even in the above-mentioned liquid crystal display device having the configuration according to the third embodiment (semiconductor device) 40c, the conductive shield layer 13c is arranged between the bottom gate type thin film transistor Tr and the pixel electrode a arranged on the upper part. For this reason, similarly as in the first embodiment, the operational characteristic in the bottom gate type thin film transistor Tr can be maintained to the stable characteristic. Also, the stabilization of the voltage applied to the pixel electrode a is realized, and it is therefore possible to carry out the display with a high reliability.

Furthermore, as the shield layer 13c arranged opposite to the organic channel layer 9 is connected to the gate electrode 3, it is possible to exclude the influence of the pixel electrode a onto Tr1 and at the same time improve the drive performance of the transistor.

### Fourth Embodiment

According to a fourth embodiment, a description will be given of an embodiment in which the present invention is applied to an active matrix system organic EL display device using an organic electroluminescence element as a light emitting element. It should be noted that in the following respective drawings, and the description will be given while the same symbols are assigned to the same components as those according to the above-mentioned first embodiment to the third embodiment.

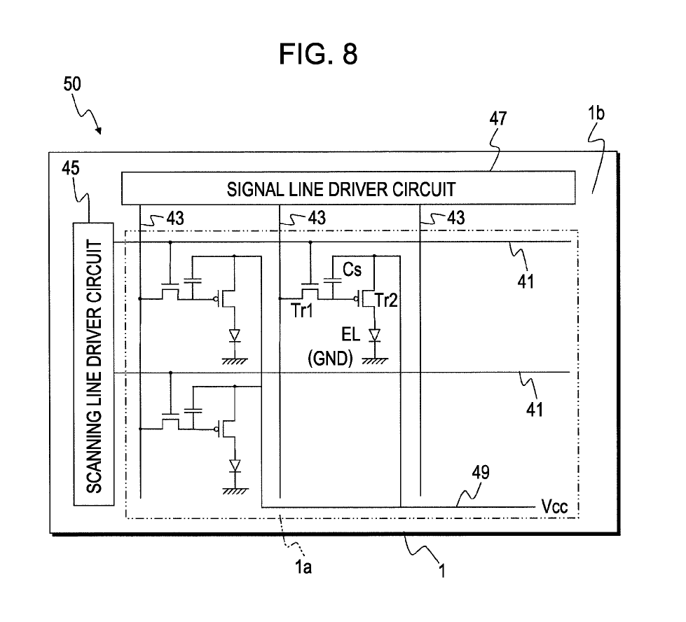

FIG. 8 is a schematic circuit configuration diagram for describing a configuration example of an organic EL display device. As shown in this drawing, the display region 1a and the peripheral region 1b are set on the substrate 1 of the organic EL display device 50. The plurality of scanning lines 41 and the plurality of signal lines are arranged lengthwise and crosswise on the display region 1a, and the pixel array sections are constructed in which one pixel is provided corresponding to the respective cross sections. Also, on the peripheral region 1b, the scanning line driver circuit 45 for scanning and driving the scanning lines 41 and the signal line driver circuit 47 for supplying the video signal in accordance with the luminance information (that is, the input signal) to the signal lines 43 are arranged.

The pixel circuit provided to the respective cross sections of the scanning lines 41 and the signal lines 43 is composed, for example, of a switching thin film transistor Tr1, the driving thin film transistor Tr2, the holding capacity Cs, and an organic electroluminescence element EL. Then, through the drive by the scanning line driver circuit 45, the video signal written from the signal line 43 via the switching thin film transistor Tr1 is held in the holding capacity Cs, a current in accordance with the held signal amount is supplied from the driving thin film transistor Tr2 to the organic electroluminescence element EL, and the organic electroluminescence element EL emits light at a luminance in accordance with this current value. It should be noted that the driving thin film transistor Tr2 and the holding capacity Cs are connected to a common power supply line (Vcc) 49.

It should be noted that the above-mentioned configuration of the pixel circuit is merely an example, and the pixel circuit may also be configured by providing a capacitance element inside the pixel circuit when necessary or further providing a plurality of transistors. Also, on the peripheral region 1b, a necessary driver circuit is added in accordance with a change in the pixel circuit.

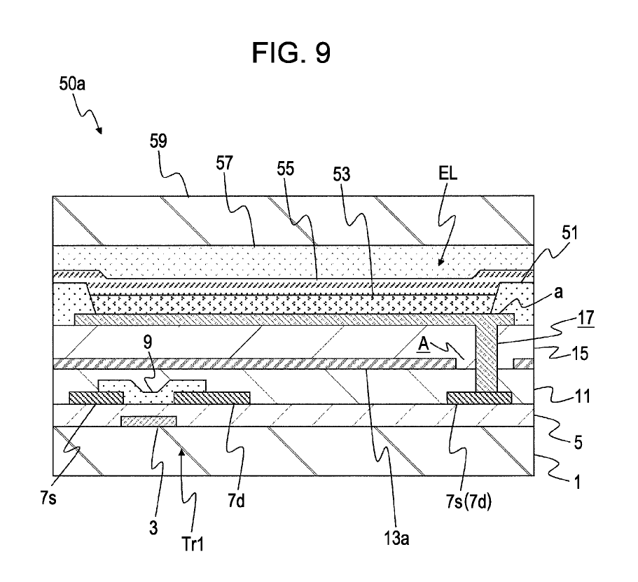

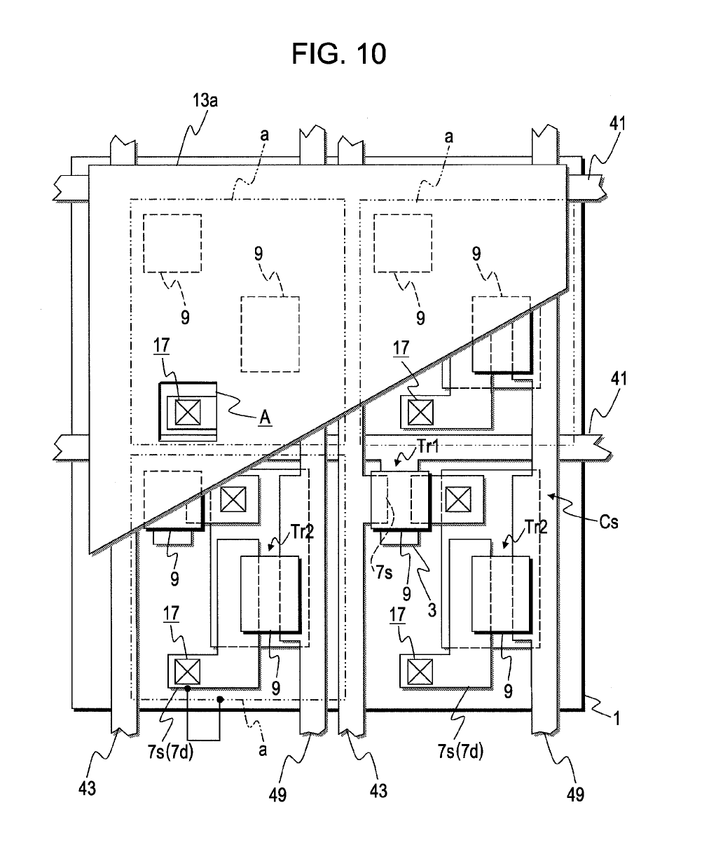

FIG. 9 shows a cross sectional view of one pixel for describing a characterizing part of an organic EL display device 50a according to the present fourth embodiment. Also, FIG. 10 shows a substantial part plane view for describing the characterizing part of the organic EL display device 50a according to the present fourth embodiment. It should be noted that a part of the plane view is cut off for the sake of description, and further, representation of a film composed of an insulative material which covers the entirety is omitted from the drawing. It should be noted that the same symbols are assigned to the same components as those of FIG. 8.

As shown in these drawings, on the respective pixels in the organic EL display device 50a according to the fourth embodiment, bottom gate type thin film transistors Tr1 and Tr2 composed of the same laminate layer configuration as the thin film transistor according to the first embodiment and the holding capacity Cs are provided. It should be noted that the cross sectional view represents only the thin film transistor Tr1.

Then, the conductive shield layer 13a which is characteristic to the present fourth embodiment is provided on the above-mentioned insulative protection film 11 covering the thin film transistors Tr1 and Tr2 and the holding capacity Cs. This shield layer 13a is provided in a state of covering at least of the top of the organic channel layer 9 in the thin film transistors Tr1 and Tr2, and in particular, according to the fourth embodiment, provided in a state of covering the entire surface of the display region. However, on this shield layer 13a, the opening section A facing the source 7s of the thin film transistor Tr2 (or the drain electrode 7d) is set to be provided for each pixel.

The above-mentioned shield layer 13a is drawn from the display region to the peripheral region to be wired and has an independently voltage controllable configuration with respect to other electrodes and wirings.

On the inter-layer insulating film 15 covering the above-mentioned shield layer 13a, the pixel electrode a (represented in the plane view by the two-dot chain line) is provided. The respective pixel electrodes a are connected via the contact section 17 provided on an inner side of the opening section A to the source 7s of the thin film transistor Tr2 (or the drain electrode 7d). This pixel electrode a is used as an anode or a cathode and herein, further, formed as a reflecting electrode.

In these pixel electrodes a, a marginal part is covered with an inter-pixel insulating film 51 in a state in which a central part is widely exposed. This inter-pixel insulating film 51 can be formed, for example, by applying an organic insulating material through spin coat, bar coater, or the like and processing through photolithography. Then, on the pixel electrode a exposed from the inter-pixel insulating film 51, organic EL material layers 53 are laminated and formed in a predetermined order. This organic EL material layer 53 is formed through a vacuum deposition method, an inkjet method, or the like. At this time, in a case where a multicolor display function is desired to be added to the display section, display colors may be separately applied for each pixel.

Also, on the inter-pixel insulating film 51 and the organic EL material layer 53, a common electrode 55 is provided in a state in which the insulation property with respect to the pixel electrode a by these layers. This common electrode 55 is used as a cathode or an anode opposite to the pixel electrode a, and herein, further constructed as a transparent electrode. This common electrode 55 is formed through the vacuum deposition method or a spattering method. Then, the respective parts where the organic EL material layer 53 is sandwiched by the pixel electrode a and the common electrode 55 become parts functioning as the organic electroluminescence element EL.

Then, a transparent substrate 59 is affixed on the above-mentioned common electrode 55 via an adhesive agent layer 57 having optical transparency to construct the organic EL display device 50a. It should be noted that although the representation in the drawing is omitted, the transparent substrate 59 side may have, for example, a layer for image quality improvement such as a color filter or the antireflection film. Also, the adhesive agent layer 57 does not necessary exist on all the pixel evenly, and for example, may exist only in the peripheral region. In this case, a physical space exists between the common electrode 55 and the transparent substrate 59, but this also suffices unless the operation is not interrupted.

The organic EL display device 50a having such a configuration is of a top emission type in which the emitted light in the organic electroluminescence element EL is taken out from the transparent substrate 59 side.

Then, even in the organic EL display device 50a having the above-mentioned configuration according to the fourth embodiment, the conductive shield layer 13a is arranged between the bottom gate type thin film transistor Tr and the pixel electrode a arranged on the upper part. For this reason, similarly as in the first embodiment, the operational characteristic in the bottom gate type thin film transistor Tr can be maintained to the stable characteristic. Also, the stabilization of the voltage applied to the pixel electrode a is realized, and it is therefore possible to carry out the display with a high reliability. Also, with the configuration in which almost the entire surface of the display region is covered by the shield layer 13a, the high gas barrier property of the shield layer 13a can prevent the degradation of the organic channel layer 9, and it is possible to improve the reliability.

Furthermore, as the potential at the shield layer 13a arranged opposite to the organic channel layer 9 can be independently controlled with respect to other electrodes in the thin film transistors Tr1 and Tr2, the operational characteristic of the thin film transistors Tr1 and Tr2 can be controlled by the potential applied to this shield layer 13a, which is also similar to the first embodiment.

### Fifth Embodiment

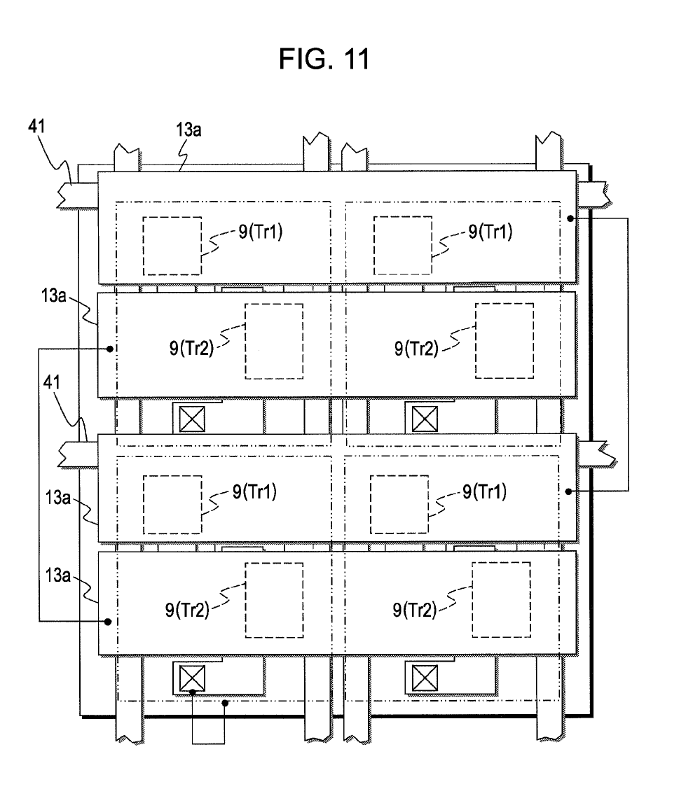

FIG. 11 shows a plane view of four pixels on a drive substrate side for describing a characterizing part of the organic EL display device 50a according to the present fifth embodiment. The fifth embodiment shown in this drawing is an embodiment like a modified example of the fourth embodiment.

As shown in FIG. 11, according to the present fifth embodiment, the shield layer 13a is divided and formed into patterns into a part covering the organic channel layer 9 of the thin film transistor Tr1 and a part covering the channel layer 9 of the thin film transistor Tr2. Then, the shield layers 13a covering the thin film transistors Tr1 are mutually connected and drawn out from the display region to the peripheral region and have an independently voltage controllable configuration with respect to other electrodes and wirings. Similarly, the shield layers 13a covering the thin film transistor Tr2 are also mutually connected and drawn out from the display region to the peripheral region and have an independently voltage controllable configuration with respect to other electrodes and wirings. The configuration except for this is set similar to that according to the fourth embodiment.

In the organic EL display device 50a having the above-mentioned configuration according to the fifth embodiment, it is possible to apply different potentials to the respective shield layers 13a subjected to the patterning in a state in which the switching thin film transistor Tr1 of the respective pixels and the driving thin film transistor Tr2 for controlling the current flowing through the organic electroluminescence element EL are individually covered. Therefore, while a consideration is given to the operational characteristic of the respective thin film transistors Tr1 and Tr2, it is possible to carry out the controls appropriate to the respective operations.

### Sixth Embodiment

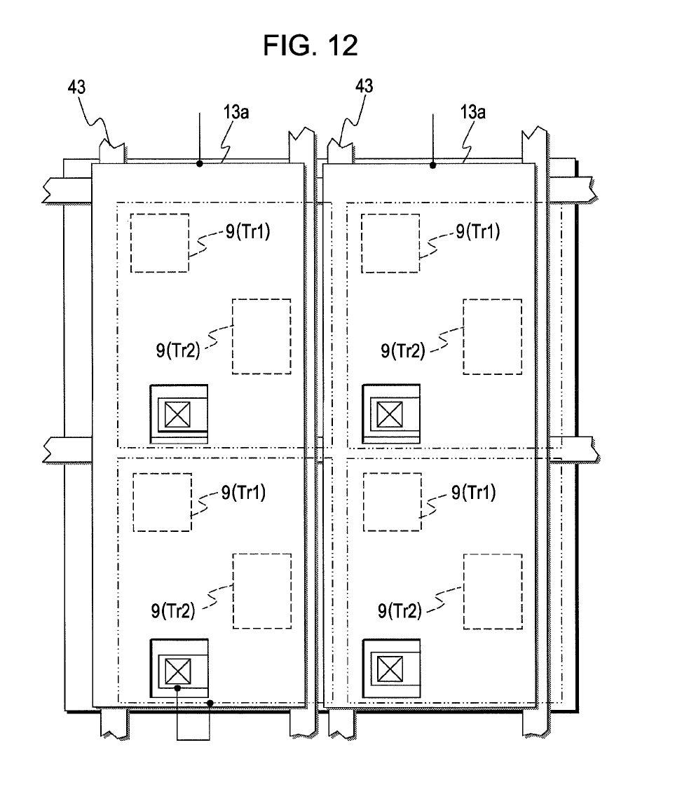

FIG. 12 shows a plane view of four pixels on a drive substrate side for describing a characterizing part of the organic EL display device 50a according to a sixth embodiment. The sixth embodiment shown in this drawing is still another example of an embodiment like a modified example of the fourth embodiment.

As shown in FIG. 12, according to the present sixth embodiment, the shield layer 13a is divided and formed into patterns for each of the pixels for taking out light of the same color. In the example shown in the drawing, this is an example in which the respective pixels for red, green, and blue are disposed along the signal line 43, and a case in which the shield layer 13a is subjected to the patterning along the signal line 43 is exemplified.

Then, the shield layers 13a subjected to the patterning are mutually connected for each of the respective colors and drawn out from the peripheral region to be wired, and have an independently voltage controllable configuration with respect to other electrodes and wirings.

Then, in the organic EL display device 50a having the above-mentioned configuration according to the sixth embodiment, it is possible to apply different potentials to the respective shield layers 13a subjected to the patterning for each of the respective display colors of red, green, and blue. To elaborate, the shield layer for red, the shield layer for green, and the shield layer for blue can be independently controlled, and for example, it is possible to carry out the hue adjustment by controlling the potentials applied to the shield layers 13a.

### Seventh Embodiment

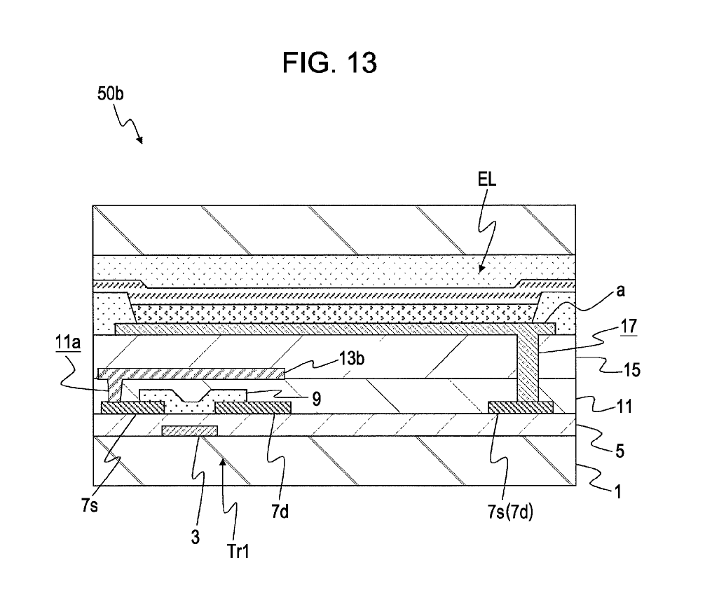

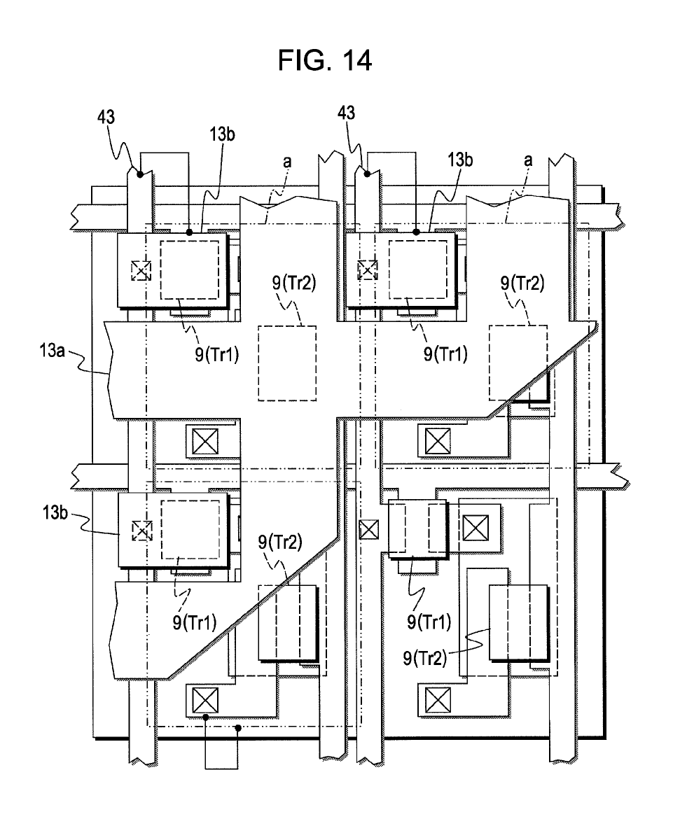

FIG. 13 shows a cross sectional view of one pixel for describing a characterizing part of an organic EL display device 50b according to a seventh embodiment. Also, FIG. 14 shows a main plane view for describing the characterizing part of the organic EL display device 50b according to the seventh embodiment. It should be noted that a part of the plane view is cut off for the sake of description, and further, representation of a film composed of an insulative material which covers the entirety is omitted from the drawing. Also, a schematic circuit configuration for describing a configuration example of the organic EL display device may be similar to the configuration described according to the fourth embodiment by using FIG. 8, and the description will be given while the same symbols are assigned to the same components as those according to the above-mentioned fourth embodiment to the sixth embodiment.

A difference between the organic EL display device 50b according to the seventh embodiment shown in these drawings and the organic EL display device according to the fourth embodiment described by using FIG. 9 and the organic EL display device according to other embodiments resides in configurations of the shield layers 13a and 13b, and the other configurations are set to be similar to one another.

That is, in the organic EL display device 50b according to the seventh embodiment, the thin film transistors Tr2 are covered by the shield layer 13a commonly provided for the respective pixels. This shield layer 13a is drawn from the display region to the peripheral region to be wired and has an independently voltage controllable configuration with respect to other electrodes and wirings.

Also, the thin film transistors Tr1 are covered by the shield layers 13b subjected to patterning for each of the pixels. These shield layers 13b are connected via the contact section 11a composed of the connecting hole provided in the protection film 11 and the conductive material filling the inside thereof to the source electrode 7s of the thin film transistor Tr1. However, it suffices that this shield layer 13b is connected to the source electrode 7s of the thin film transistor Tr1, and in consideration of the layout of the contact section 11a, it may also be connected to a part of the signal line 43 provided extending from the source electrode 7s (see the plane view).

It should be noted that, if possible in terms of the pixel layout, the respective shield layers 13b may also be divided for each part which covers the thin film transistors Tr1 sharing the one signal line 43 or may be subjected to the patterning along the signal line 43 in a state in which at least the organic channel layer 9 of the thin film transistor Tr1 is covered. In this case, the respective shield layers 13b covering the plurality of thin film transistors Tr in a state of sharing the one signal line 43 may be connected to the signal line 43 at least at one position, and the connecting position may also be in the peripheral region. Even in this case too, it suffices that the shield layer 13a covering the thin film transistors Tr2 has a configuration of being mutually connected in the periphery of the display region and commonly driven.

In the organic EL display device 50b having the above-mentioned configuration according to the seventh embodiment, as the shield layer 13a of the driving thin film transistor Tr2 is common to all the pixels, it is possible to control the driving thin film transistor Tr2 in all the pixels at once to adjust the luminance. Furthermore, as the shield layer 13b arranged opposite to the organic channel layer 9 of the switching thin film transistor Tr1 is connected to the source electrode 7s, the influence of the potential at the pixel electrode a onto Tr1 is eliminated, and it is possible to realize the Tr1 stable operation and the operational voltage reduction.

### Eighth Embodiment

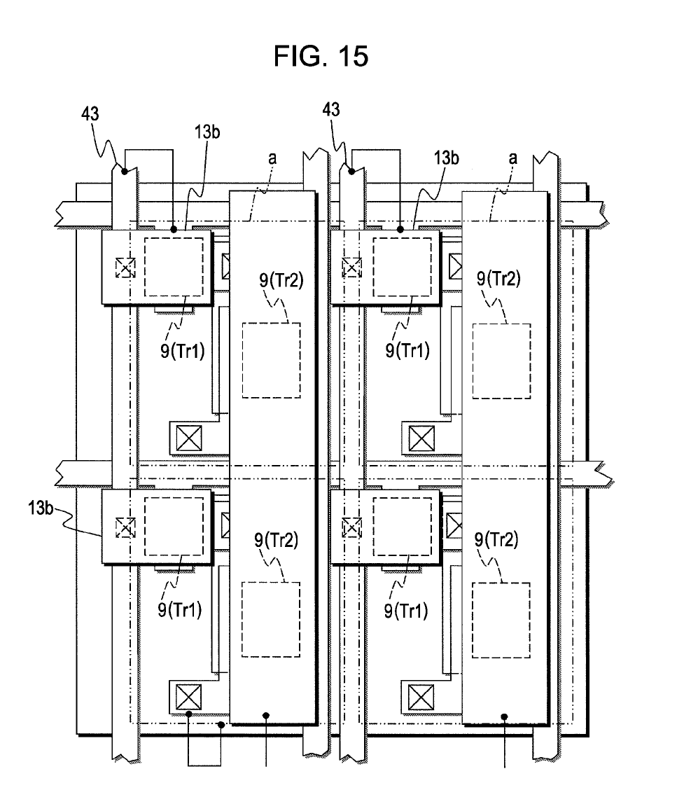

FIG. 15 shows a plane view of four pixels on a drive substrate side for describing a characterizing part of the organic EL display device 50b according to the present eighth embodiment. The eighth embodiment shown in this drawing is an embodiment like a modified example of the seventh embodiment.

As shown in FIG. 15, according to the present eighth embodiment, the shield layer 13a covering the thin film transistors Tr2 is divided for each of the pixels taking out light of the same color and formed into patterns. In the example shown in the drawing, this is an example in which the respective pixels for red, green, and blue are disposed along the signal line 43, and a case in which the shield layer 13a is subjected to the patterning along the signal line 43 is exemplified.

Also, in such a configuration too, the respective shield layers 13b may also be divided for each part which covers the thin film transistors Tr1 sharing the one signal line 43 or may be subjected to the patterning along the signal line 43 in a state in which at least the organic channel layer 9 of the thin film transistor Tr1 is covered. Then, the respective shield layers 13b covering the plurality of thin film transistors Tr in a state of sharing the one signal line 43 may be connected to the signal line 43 at least at one position, and the connecting position may also be in the peripheral region.

Then, in the organic EL display device 50b having the above-mentioned configuration according to the eighth embodiment, it is possible to apply different potentials to the respective shield layers 13a subjected to the patterning for each of the respective display colors of red, green, and blue. To elaborate, the shield layer for red, the shield layer for green, and the shield layer for blue can be independently controlled, and for example, it is therefore possible to carry out the hue adjustment by controlling the potentials applied to the shield layers 13a. Furthermore, as the shield layer 13b arranged opposite to the organic channel layer 9 of the switching thin film transistor Tr1 is connected to the source electrode 7s, the influence of the potential at the pixel electrode a onto Tr1 is eliminated, and it is possible to realize the Tr1 stable operation and the operational voltage reduction.

### Ninth Embodiment

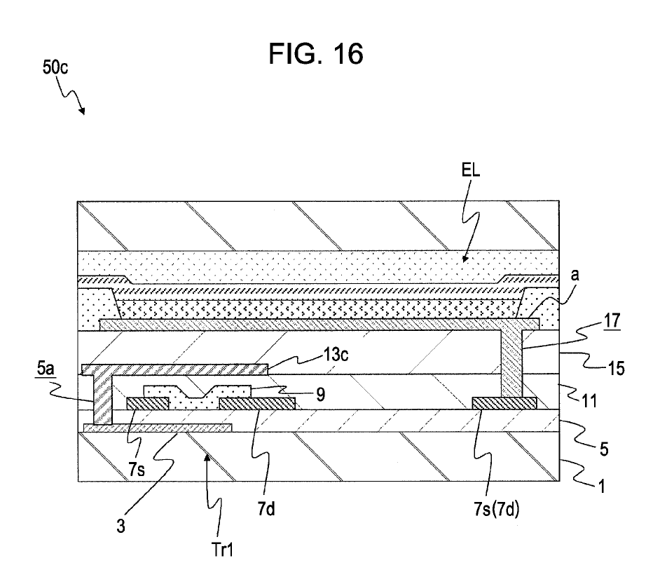

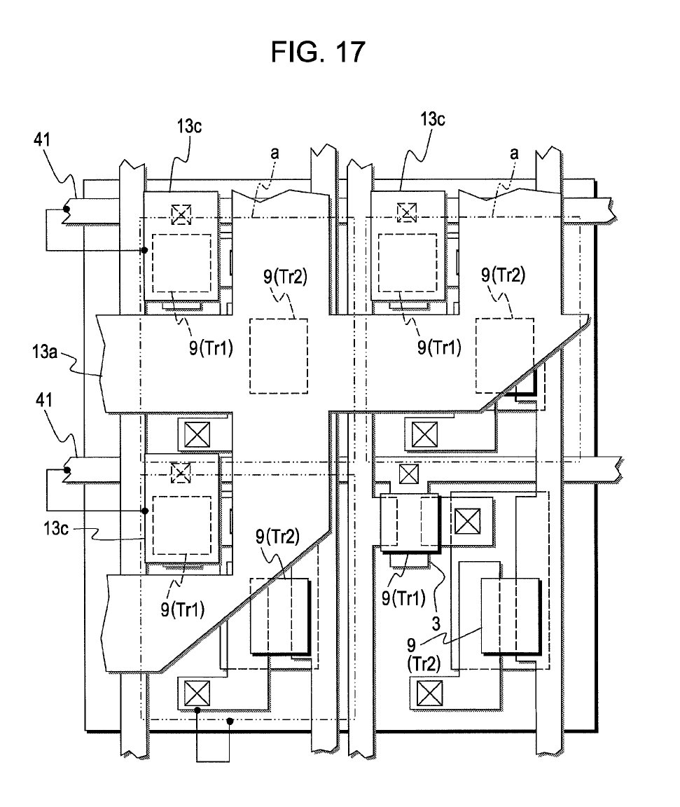

FIG. 16 shows a cross sectional view of one pixel for describing a characterizing part of an organic EL display device 50c according to the present ninth embodiment. Also, FIG. 17 shows a substantial part plane view for describing a characterizing part of the organic EL display device 50c according to the present ninth embodiment. It should be noted that a part of the plane view is cut off for the sake of description, and further, representation of a film composed of an insulative material which covers the entirety is omitted from the drawing. Also, a schematic circuit configuration for describing a configuration example of the organic EL display device may be similar to the configuration described according to the fourth embodiment by using FIG. 8, and, and the description will be given while the same symbols are assigned to the same components as those according to the above-mentioned fourth embodiment to the seventh embodiment.

A difference between the organic EL display device 50c according to the ninth embodiment shown in these drawings and the organic EL display device according to the fourth embodiment described by using FIG. 9 and the organic EL display device according to other embodiments resides in configurations of the shield layers 13a and 13c, and the other configurations are set to be similar to one another.

That is, in the organic EL display device 50c according to the ninth embodiment, the thin film transistors Tr2 are covered with the shield layer 13a commonly provided to the respective pixels. This shield layer 13a is drawn from the display region to the peripheral region to be wired and has an independently voltage controllable configuration with respect to other electrodes and wirings.

Also, the thin film transistors Tr1 are covered by the shield layers 13c subjected to patterning for each of the pixels. These shield layers 13c are connected via the connecting holes provided in the protection film 11 and the gate insulating film 5 and the contact section 5a composed of a conductive material filling the inside thereof to the gate electrode 3 of the thin film transistor Tr1. However, it suffices that this shield layer 13c is connected the gate electrode 3 of the thin film transistor Tr1, and in consideration of the layout of the contact section 5a, may also be connected at a part of the scanning line 41 (see the plane view).

It should be noted that, if possible in terms of the pixel layout, the respective shield layers 13c may also be divided for each part covering the thin film transistors Tr which share one scanning line 41 or may be subjected to the patterning along the scanning line 41 in a state in which at least the organic channel layer 9 of the thin film transistor Tr1 is covered. In this case, it suffices that the respective shield layers 13c covering the plurality of thin film transistors Tr in a state of sharing one scanning line 41 is connected to the scanning line 41 at least one position, and the connecting position may also be in the peripheral region. Even in this case too, it suffices that the shield layer 13a covering the thin film transistors Tr2 has a configuration of being mutually connected in the periphery of the display region and commonly driven.

In the organic EL display device 50c having the above-mentioned configuration according to the ninth embodiment, as the shield layer 13a of the driving thin film transistor Tr2 is common to all the pixels, it is possible to control the driving thin film transistor Tr2 in all the pixels at once to adjust the luminance. Furthermore, as the shield layer 13c arranged opposite to the organic channel layer 9 is connected to the gate electrode 3, it is possible to exclude the influence of the pixel electrode a onto Tr1 and at the same time improve the drive performance of the transistor.

### Tenth Embodiment

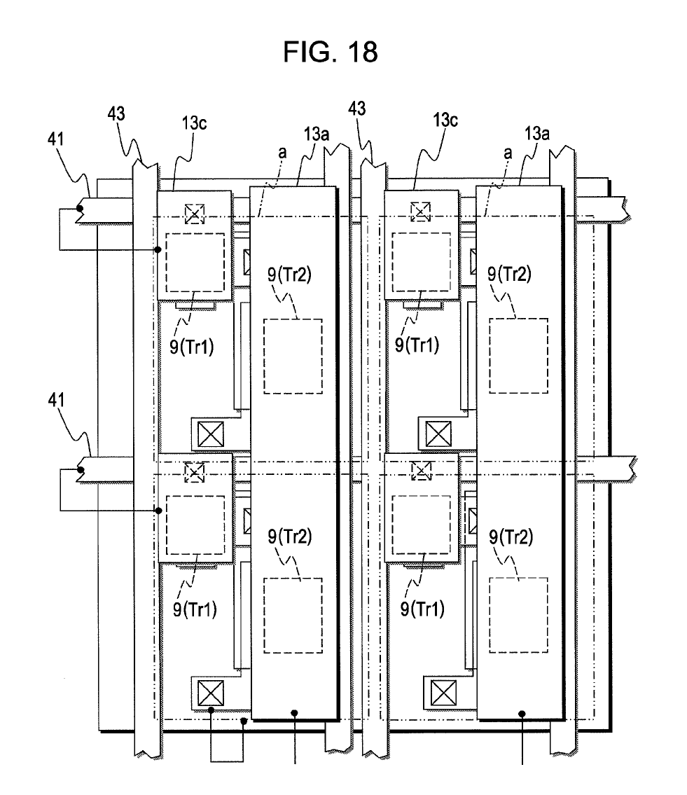

FIG. 18 shows a plane view of four pixels on a drive substrate side for describing a characterizing part of the organic EL display device 50c according to the present tenth embodiment. The tenth embodiment shown in this drawing is an embodiment like a modified example of the ninth embodiment.

According to the present tenth embodiment, as shown in FIG. 18, the shield layer 13a covering the thin film transistors Tr2 is divided for each of the pixels taking out light of the same color and formed into patterns. In the example shown in the drawing, this is an example in which the respective pixels for red, green, and blue are disposed along the signal line 43, and a case in which the shield layer 13a is subjected to the patterning along the signal line 43 is exemplified.

Then, in the organic EL display device 50c having the above-mentioned configuration according to the tenth embodiment, it is possible to apply different potentials to the respective shield layers 13a subjected to the patterning for each of the respective display colors of red, green, and blue. To elaborate, the shield layer for red, the shield layer for green, and the shield layer for blue can be independently controlled, and for example, it is possible to carry out the hue adjustment by controlling the potentials applied to the shield layers 13a. Furthermore, as the shield layer 13c arranged opposite to the organic channel layer 9 is connected to the gate electrode 3, it is possible to exclude the influence of the pixel electrode a onto Tr1 and at the same time improve the drive performance of the transistor.

### Eleventh Embodiment

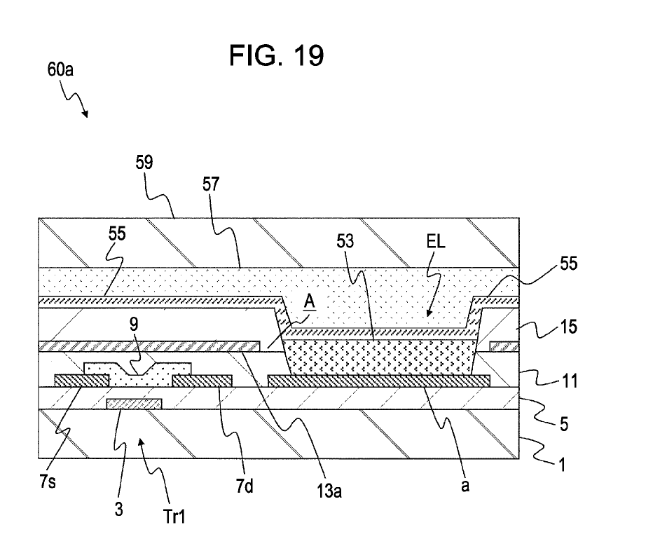

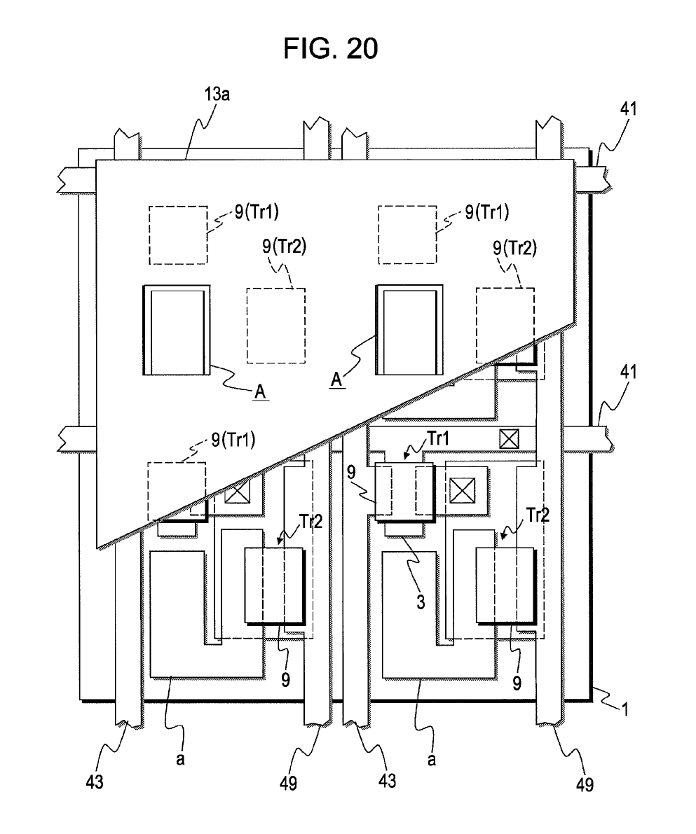

FIG. 19 shows a cross sectional view of one pixel for describing a characterizing part of an organic EL display device 60a according to the present eleventh embodiment. Also, FIG. 20 shows a substantial part plane view for describing the characterizing part of the organic EL display device 60a according to the present eleventh embodiment. It should be noted that a part of the plane view is cut off for the sake of description, and further, representation of a film composed of an insulative material which covers the entirety is omitted from the drawing. Also, a schematic circuit configuration for describing a configuration example of the organic EL display device may be similar to the configuration described according to the fourth embodiment by using FIG. 8, and the description will be given while the same symbols are assigned to the same components as those according to the above-mentioned fourth embodiment to the tenth embodiment.

A difference between the organic EL display device 60a according to the eleventh embodiment shown in these drawings and the top emission type organic EL display device according to the fourth embodiment described by using FIGS. 9 and 10 resides in a configuration of the pixel electrode a and a configuration of the shield layer 13a, and the other configurations are set to be similar to one another.

That is, in the organic EL display device 60a according to the eleventh embodiment, the pixel electrode a is composed of the same layer as the source electrode 7s and the drain electrode 7d of the thin film transistors Tr1 and Tr2. The respective pixel electrodes a are provided in a state of extending from the source electrode 7s (or the drain electrode 7d) of the thin film transistor Tr2. Also, these pixel electrodes a are used as a cathode or an anode but are set herein to be formed of a conductive material having optical transparency with respect to the visible light or having semi-transmissive property (having a finite transmissivity with respect to the visible light). At this time, it is preferable that the pixel electrode a has a transmissivity of preferably about 70% with respect to the visible light.

Also, the insulative protection film 11 covering the thin film transistors Tr1 and Tr2 and the holding capacity Cs is formed as the inter-pixel insulating film patterned into a shape which covers the marginal part in a state in which the central part of the pixel electrode a is widely exposed.

Then, the shield layer 13a provided on this protection film 11 is provided in a state of covering at least the organic channel layer 9 of the thin film transistors Tr1 and Tr2, and in particular, according to the present eleventh embodiment, the opening section A for widely exposing the pixel electrode a is set to be provided for each pixel. The above-mentioned shield layer 13a is drawn from the display region to the peripheral region to be wired and has an independently voltage controllable configuration with respect to other electrodes and wirings.

Also, the inter-layer insulating film 15 covering this shield layer 13a is also formed as the inter-pixel insulating film patterned into a shape which covers the marginal part of the pixel electrode a in a state in which the central part of the pixel electrode a is widely exposed. However, the shield layer 13a is in a state of being completely covered with the inter-layer insulating film 15.

An opening portion for exposing the pixel electrode a may also be formed in the protection film 11 and the inter-layer insulating film 15 constituting such an inter-pixel insulating film through continuous pattern etching.

It should be noted that the laminate film formation of the organic EL material layer 53 on the pixel electrode a exposed from the inter-pixel insulating film, the provision of the common electrode 55 by the inter-pixel insulating film and the organic EL material layer 53 in a state of maintaining the insulation property with respect to the pixel electrode a, and then, the respective parts sandwiched by the pixel electrode a and the common electrode 55 and the organic EL material layer 53 which function as the organic electroluminescence element EL are similar to those described according to the fourth embodiment. However, the common electrode 55 is set to be configured as a reflecting electrode herein.

The organic EL display device 60a having such a configuration is of a bottom emission type in which emitted light in the organic electroluminescence element EL transmits through the pixel electrode a to be taken out from the substrate 1 side.

Then, in the organic EL display device 60a having the above-mentioned configuration according to the eleventh embodiment, the conductive shield layer 13a is arranged between the bottom gate type thin film transistors Tr1 and tr2 and the common electrode 55 arranged on the upper part. For this reason, it is possible to obtain effects similar to those according to the first embodiment. That is, without being affected by the potential applied to the common electrode 55, the operational characteristic in the bottom gate type thin film transistor Tr can be maintained to the stable characteristic. Also, the stabilization of the voltage applied to the pixel electrode a is realized, and it is therefore possible to carry out the display with a high reliability. Also, with the configuration in which almost the entire surface of the display region is covered by the shield layer 13a, the high gas barrier property of the shield layer 13a prevents the degradation of the organic channel layer 9, and it is possible to improve the reliability.

Furthermore, as the potential at the shield layer 13a arranged opposite to the organic channel layer 9 in the thin film transistors Tr1 and Tr2 can be independently controlled with respect to other electrodes, it is possible to control the operational characteristic of the thin film transistors Tr1 and Tr2 by the potential applied to this shield layer 13a, which is also similar to the first embodiment.

### Twelfth Embodiment

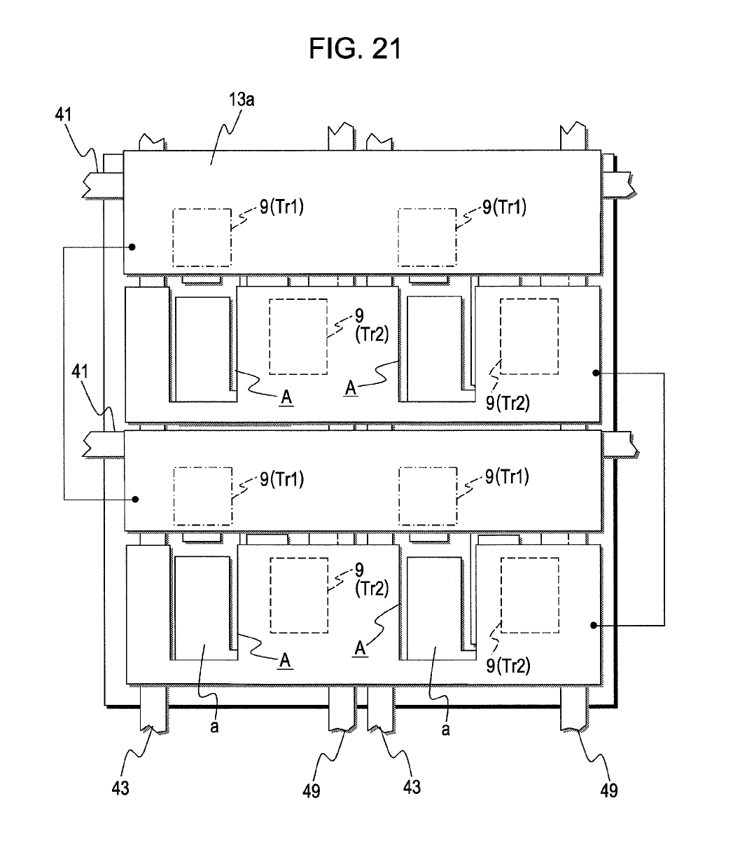

FIG. 21 shows a plane view of four pixels on a drive substrate side for describing a characterizing part of the organic EL display device 60a according to a twelfth embodiment. The twelfth embodiment shown in this drawing is an embodiment like a modified example of the eleventh embodiment.

As shown in FIG. 21, according to the present twelfth embodiment, the shield layer 13a is divided and formed into patterns into a part covering the organic channel layer 9 of the thin film transistor Tr1 and a part covering the channel layer 9 of the thin film transistor Tr2. Then, the shield layers 13a covering the thin film transistors Tr1 are mutually connected and drawn out from the display region to the peripheral region and have an independently voltage controllable configuration with respect to other electrodes and wirings. Similarly, the shield layers 13a covering the thin film transistors Tr2 are also mutually connected and drawn out from the display region to the peripheral region and have an independently voltage controllable configuration with respect to other electrodes and wirings. The configuration except for this is set similar to that according to the eleventh embodiment.

In the organic EL display device 60a having the above-mentioned configuration according to the twelfth embodiment, it is possible to apply different potentials to the respective shield layers 13a subjected to the patterning in a state in which the switching thin film transistor Tr1 of the respective pixels and the driving thin film transistor Tr2 for controlling the current flowing through the organic electroluminescence element EL are individually covered. Therefore, while a consideration is given to the operational characteristic of the respective thin film transistors Tr1 and Tr2, it is possible to carry out the controls appropriate to the respective operations.

### Thirteenth Embodiment

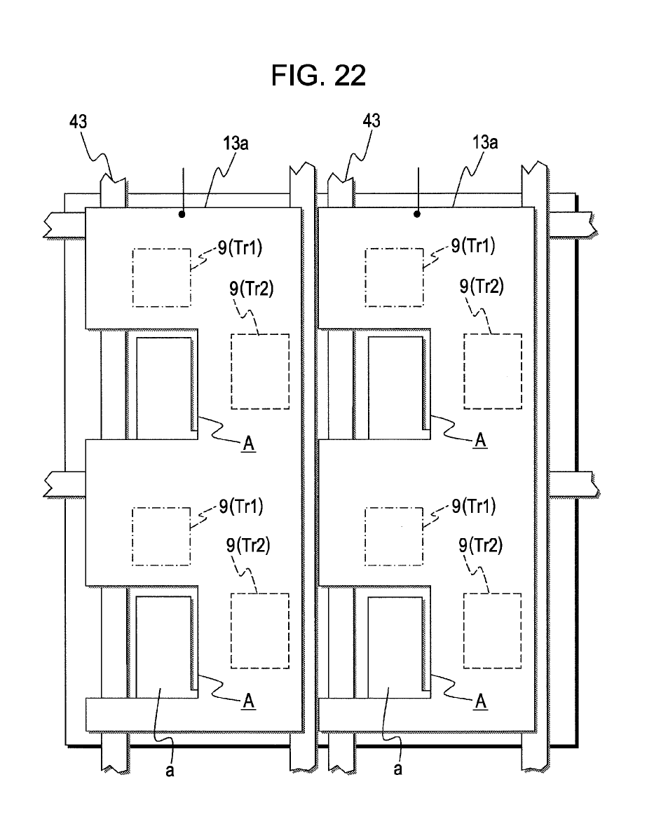

FIG. 22 shows a plane view of four pixels on a drive substrate side for describing a characterizing part of the organic EL display device 60a according to a thirteenth embodiment. The thirteenth embodiment shown in this drawing is still another example of an embodiment like a modified example of the eleventh embodiment.

As shown in FIG. 22, according to the present thirteenth embodiment, the shield layer 13a is divided and formed into patterns for each of the pixels for taking out light of the same color. In the example shown in the drawing, this is an example in which the respective pixels for red, green, and blue are disposed along the signal line 43, and a case in which the shield layer 13a is subjected to the patterning along the signal line 43 is exemplified.

Then, the shield layers 13a subjected to the patterning are mutually connected for each of the respective colors and drawn out from the peripheral region to be wired, and have an independently voltage controllable configuration with respect to other electrodes and wirings.

Then, in the organic EL display device 60a having the above-mentioned configuration according to the twenty second embodiment, it is possible to apply different potentials to the respective shield layers 13a subjected to the patterning for each of the respective display colors of red, green, and blue. To elaborate, the shield layer for red, the shield layer for green, and the shield layer for blue can be independently controlled, and for example, it is possible to carry out the hue adjustment by controlling the potentials applied to the shield layers 13a.

### Fourteenth Embodiment

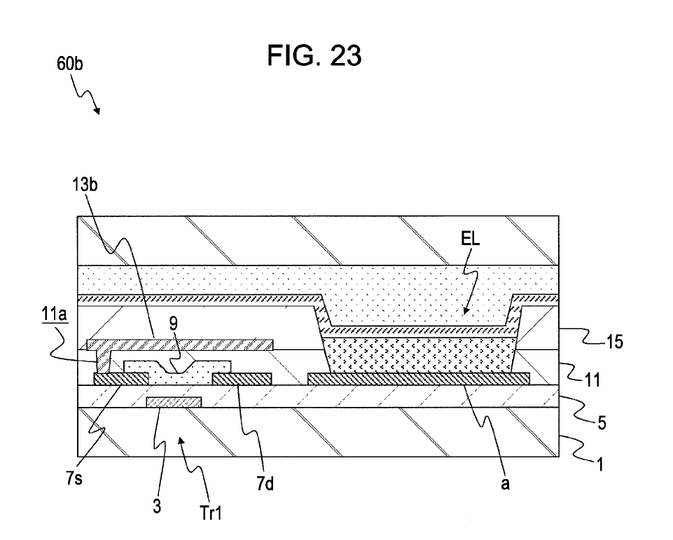

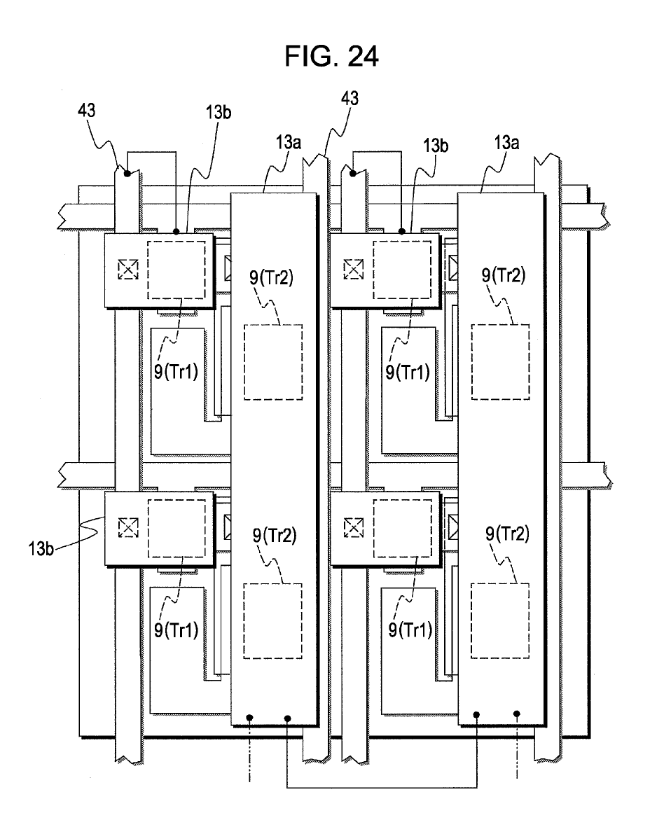

FIG. 23 shows a cross sectional view of one pixel for describing a characterizing part of an organic EL display device 60b according to a fourteenth embodiment. Also, FIG. 24 shows a substantial part plane view for describing the characterizing part of the organic EL display device 60b according to the present fourteenth embodiment. It should be noted that a part of the plane view is cut off for the sake of description, and further, representation of a film composed of an insulative material which covers the entirety is omitted from the drawing. Also, a schematic circuit configuration for describing a configuration example of the organic EL display device may be similar to the configuration described according to the fourth embodiment by using FIG. 8, and the description will be given while the same symbols are assigned to the same components as those according to the above-mentioned embodiments.

A difference between the organic EL display device 60b according to the fourteenth embodiment shown in these drawings and the bottom emission type organic EL display device according to the eleventh embodiment described by using FIG. 19 and other embodiments resides in configurations of the shield layers 13a and 13b, and the other configurations are set to be similar to one another.

That is, in the organic EL display device 60b according to the fourteenth embodiment, the thin film transistors Tr2 are covered by the shield layer 13a commonly provided for the respective pixels. These shield layers 13a are mutually connected and drawn from the display region to the peripheral region to be wired, and have an independently voltage controllable configuration with respect to other electrodes and wirings.

Also, the thin film transistors Tr1 are covered by the shield layers 13b subjected to patterning for each of the pixels. These shield layers 13b are connected via the contact section 11a composed of the connecting hole provided in the protection film 11 and the conductive material filling the inside thereof to the source electrode 7s of the thin film transistor Tr1. However, it suffices that this shield layer 13b is connected to the source electrode 7s of the thin film transistor Tr1, and in consideration of the layout of the contact section 11a, it may also be connected to a part of the signal line 43 provided extending from the source electrode 7s (see the plane view).

It should be noted that, if possible in terms of the pixel layout, the respective shield layers 13b is divided for each part which covers the thin film transistors Tr1 sharing the one signal line 43 or may be subjected to the patterning along the signal line 43 in a state in which at least the organic channel layer 9 of the thin film transistor Tr1 is covered. In this case, the respective shield layers 13b covering the plurality of thin film transistors Tr in a state of sharing the one signal line 43 may be connected to the signal line 43 at least at one position, and the connecting position may also be in the peripheral region. Even in this case too, it suffices that the shield layer 13a covering the thin film transistors Tr2 has a configuration of being mutually connected in the periphery of the display region and commonly driven.

In the organic EL display device 60b having the above-mentioned configuration according to the fourteenth embodiment, as the shield layer 13a of the driving thin film transistor Tr2 is common to all the pixels, it is possible to control the driving thin film transistor Tr2 in all the pixels at once to adjust the luminance. Furthermore, as the shield layer 13b arranged opposite to the organic channel layer 9 of the switching thin film transistor Tr1 is connected to the source electrode 7s, the influence of the potential at the pixel electrode a onto Tr1 is eliminated, and it is possible to realize the Tr1 stable operation and the operational voltage reduction.

It should be noted that according to the present fourteenth embodiment, it suffices that the potentials at the shield layers 13a provided in a state of covering at least the organic channel layer 9 of the thin film transistor Tr2 can be independently controlled. For this reason, in a case where the shield layer 13a is subjected to the patterning along the signal line 43 for each of the pixels taking out light of the same color, it is also possible to adopt a configuration in which the potentials applied to the shield layers 13a are individually controlled by the terminal represented in the drawing by the two-dot chain line for each of the respective colors. According to this, it is possible to apply different potentials to the respective shield layers 13a subjected to the patterning for each of the respective display colors of red, green, and blue. To elaborate, the shield layer for red, the shield layer for green, and the shield layer for blue can be independently controlled, and for example, by controlling the potential applied to the shield layer 13a, it is possible to carry out the hue adjustment.

### Fifteenth Embodiment

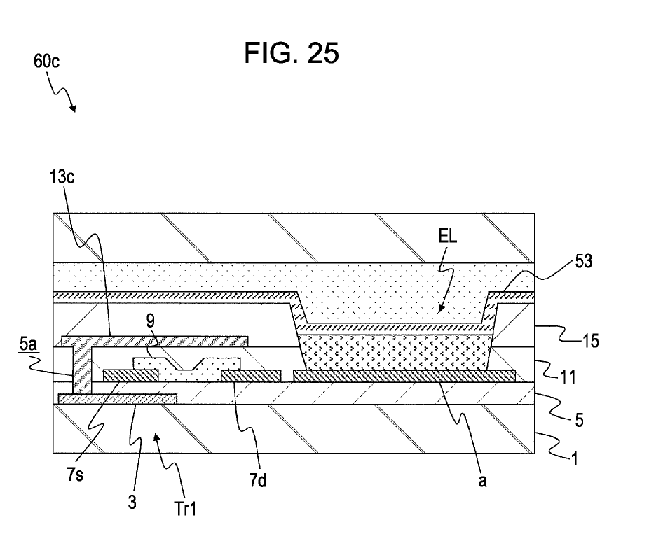

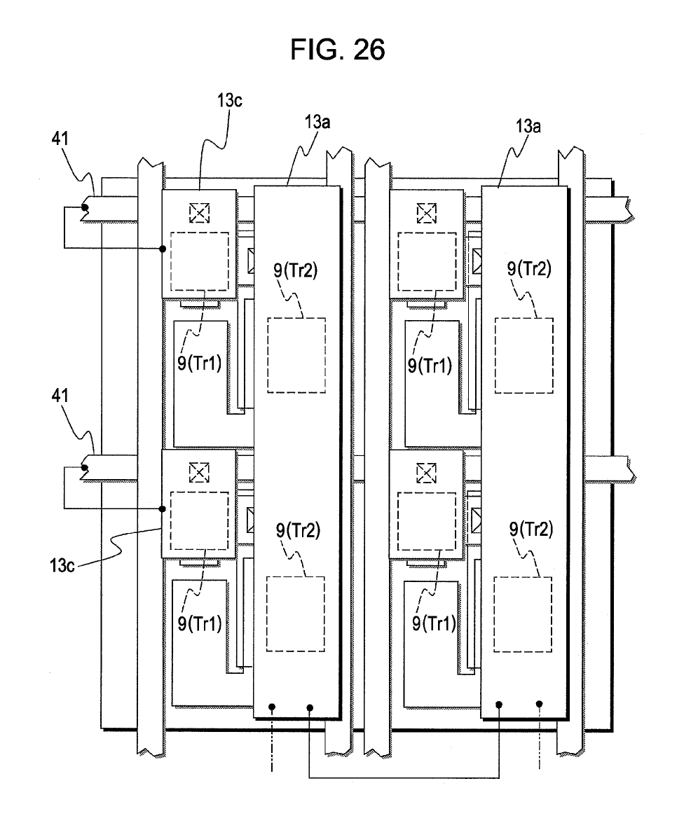

FIG. 25 shows a cross sectional view of one pixel for describing a characterizing part of an organic EL display device 60c according to a fifteenth embodiment. Also, FIG. 26 shows a substantial part plane view for describing the characterizing part of the organic EL display device 60c according to the present fifteenth embodiment. It should be noted that a part of the plane view is cut off for the sake of description, and further, representation of a film composed of an insulative material which covers the entirety is omitted from the drawing. Also, a schematic circuit configuration for describing a configuration example of the organic EL display device may be similar to the configuration described according to the fourth embodiment by using FIG. 8, and the description will be given while the same symbols are assigned to the same components as those according to the above-mentioned embodiments.

A difference between the organic EL display device 60c according to the fifteenth embodiment shown in these drawings and the bottom emission type organic EL display device according to the eleventh embodiment described by using FIG. 19 and other embodiments resides in configurations of the shield layers 13a and 13c, and the other configurations are set to be similar to one another.

That is, in the organic EL display device 60c according to the fifteenth embodiment, the thin film transistors Tr2 are covered by the shield layer 13a commonly provided for the respective pixels. These shield layer 13a are mutually connected to be drawn from the display region to the peripheral region to be wired and have an independently voltage controllable configuration with respect to other electrodes and wirings.

Also, the thin film transistors Tr1 are covered by the shield layers 13c subjected to patterning for each of the pixels. These shield layer 13c are connected via the contact section 5a composed of the connecting holes provided in the protection film 11 and the gate insulating film 5 and a conductive material filling the inside thereof to the gate electrode 3 of the thin film transistor Tr1. However, as it suffices that this shield layer 13c is connected to the gate electrode 3 of the thin film transistor Tr1, in consideration of the layout of the contact section 11a, it may also be connected at a part of the scanning line 41 (see the plane view).

It should be noted that, if possible in terms of the pixel layout, the respective shield layers 13c are divided for each part covering the thin film transistors Tr which share one scanning line 41 and may also be subjected to the patterning along the scanning line 41 in a state of covering at least the organic channel layer 9 of the thin film transistor Tr1. In this case, it suffices that the respective shield layers 13c covering the plurality of thin film transistors Tr in a state of sharing one scanning line 41 is connected to the scanning line 41 at least one position, and the connecting position may also be in the peripheral region. Even in this case too, it suffices that the shield layer 13a covering the thin film transistors Tr2 has a configuration of being mutually connected in the periphery of the display region and commonly driven.

In the organic EL display device 60c having the above-mentioned configuration according to the fifteenth embodiment, as the shield layer 13a of the driving thin film transistor Tr2 is common to all the pixels, it is possible to adjust the luminance by controlling the driving thin film transistor Tr2 in all the pixels at once. Furthermore, as the shield layer 13c arranged opposite to the organic channel layer 9 is connected to the gate electrode 3, it is possible to exclude the influence of the pixel electrode a onto Tr1 and at the same time improve the drive performance of the transistor.

It should be noted that according to the present fifteenth embodiment, it suffices that the potentials at the shield layers 13a can be independently controlled in a state in which at least the organic channel layer 9 of the thin film transistor Tr2 is covered. For this reason, in a case where the shield layer 13a is subjected to the patterning along the signal line 43 for each of the pixels taking out light of the same color, it is possible to adopt a configuration in which the potentials applied to the shield layers 13a are controlled by the terminal represented in the drawing by the two-dot chain line for each of the respective colors. According to this, it is possible to apply different potentials to the respective shield layers 13a subjected to the patterning for each of the respective display colors of red, green, and blue. To elaborate, the shield layer for red, the shield layer for green, and the shield layer for blue can be independently controlled, and for example, by controlling the potential applied to the shield layer 13a, it is possible to carry out the hue adjustment.

### Sixteenth Embodiment

According to a sixteenth embodiment, a description will be given of an embodiment in which the present invention is applied to an electrophoretic type display device of the active matrix system.

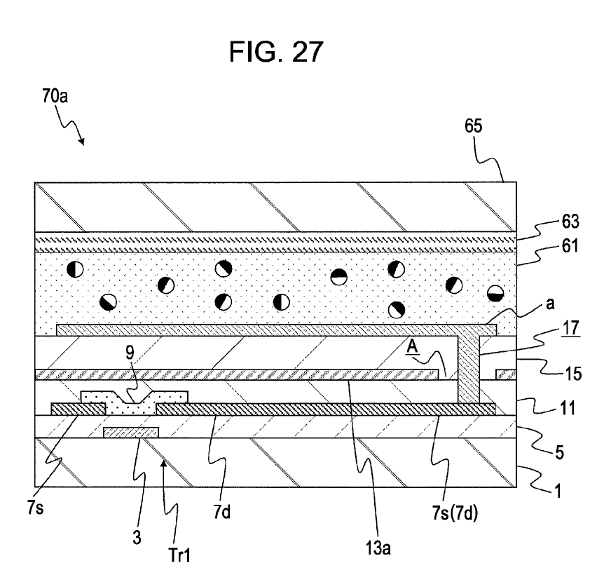

FIG. 27 shows a cross sectional view of one pixel for describing a characterizing part of an electrophoretic type display device 70a according to the sixteenth embodiment. It should be noted that a schematic circuit configuration for describing a configuration example of the electrophoretic type display device 70a may be similar to the configuration described according to the first embodiment by using FIG. 1, and the description will be given while the same symbols are assigned to the same components as those according to the above-mentioned embodiments.

This electrophoretic type display device 70a is similar to the liquid crystal display device described according to the first embodiment by using FIGS. 2 and 3, and up to the pixel electrode a is configured from the substrate 1 side.

To elaborate, the shield layer 13a is provided on the insulative protection film 11 covering the thin film transistor Tr and the holding capacity Cs in a state of covering at least the top of the organic channel layer 9 (in a state of covering the entire surface of the display region herein), and the shield layer 13a is drawn from the display region to the peripheral region to be wired and has an independently voltage controllable configuration with respect to other electrodes and wirings.

Then, a sheet-like electrophoretic type display section 61, a common electrode 63 arranged opposite to the pixel electrode a, and a transparent substrate 65 are provided in a state of covering the top of this pixel electrode a. These are provided on an upper side of the substrate 1 while the transparent substrate 65 in which the common electrode 63 and the electrophoretic type display section 61 are laminated and formed is affixed on the pixel electrode a side (to perform lamination).

It should be noted that although the representation in the drawing is omitted, on the transparent substrate 65 side, for example, layers for the image quality improvement such as a color filter and an antireflection film may also be provided. In this case, after the transparent substrate 65 is affixed on the pixel electrode a, these layers for the image quality improvement are formed.

In the electrophoretic display device (semiconductor device) 70a having the above-mentioned configuration according to the sixteenth embodiment, the effect similar to the liquid crystal display device according to the first embodiment can be obtained.

It should be noted that in the present active matrix type electrophoretic display device too, the shield layer is set to have a configuration similar to that of the second embodiment (FIGS. 4 and 5) and the third embodiment (FIGS. 6 and 7), it is possible to obtain effect similar to those according to these respective embodiments.

Then, according to the above-mentioned respective embodiments, the case in which the liquid crystal display device is exemplified and the active matrix type pixel circuit is composed of one piece of the thin film transistor has been described, and the case in which the organic EL display device is exemplified and the active matrix type pixel circuit is composed of two pieces of the thin film transistors has been described. However, the present invention can also be further applied to the liquid crystal display device, the organic EL display device, the electrophoretic display device, and further other active matrix type display devices in which the pixel circuit is composed of three or more pieces of the thin film transistors, and it is possible to obtain similar effects. Also, in a case where the pixel circuit is composed of three or more pieces of the thin film transistors, the shield layer may be divided for each of the thin film transistors having the respective functions, and the connection may be appropriately established to the divided patterns or electrodes.

To elaborate, irrespective of the number of the thin film transistors Tr constructing the pixel circuit, by devising the wiring of the shield layer in consideration of the operational conditions of the respective thin film transistors, the compensation in conformity to the roles of the respective thin film transistors can be realized.

### Seventeenth Embodiment

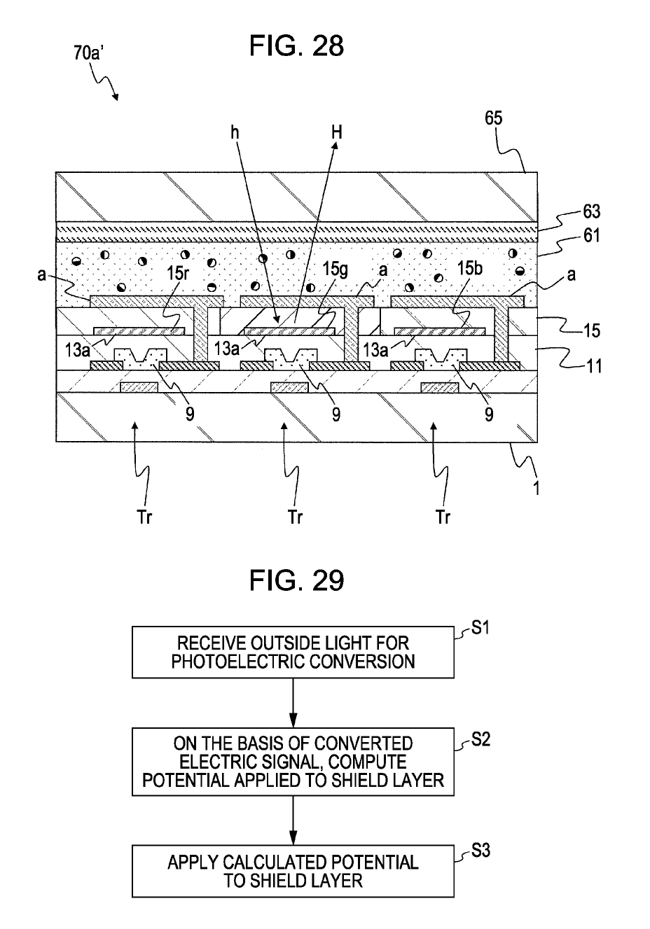

FIG. 28 is a cross sectional view of an electrophoretic type display device the present invention is applied. On the basis of this drawing, an embodiment of a color display active matrix type display device to which the present invention is applied will be described.

In an electrophoretic display device 70a′ shown in this drawing, for example, a red (R) pixel, a green (G) pixel, and a blue (B) pixel which are three primary colors of light are set as one set, and a plurality of sets are disposed on the substrate 1. A difference between the configurations of the respective pixels and the sixteenth embodiment resides in a point that the shield layer 13a is limited to one composed of a reflecting material, a point that the inter-layer insulating films 15 covering this are provided with configurations different for the respective pixels, and further, a point that the pixel electrode a is composed of a transparent electrode. Other configurations are similar to those according to the sixteenth embodiment. That is, the shield layer 13a is composed, for example, of a material which reflects the visible light such as aluminum. In particular, the visible light reflectance of this shield layer 13a becomes an important factor exerting an influence on the display performance. Therefore, in order to improve the visible light reflectance of the shield layer 13a, irregular concavity and convexity may also be prepared on the surface of the shield layer 13a.

Also, the inter-layer insulating films 15 are composed of the respective inter-layer insulating films 15r, 15g, and 15b colored for each of the red (R) pixel, the green (G) pixel, and the blue (B) pixel and have a color filter function (color selection function). To elaborate, the inter-layer insulating film 15r having a filter function of allowing only red light to transmit is provided to the red (R) pixel, and for others, the similar inter-layer insulating films 15g and 15b are provided to each of the pixels of the respective colors. It should be noted that in order to increase the color purity, the inter-layer insulating films 15r, 15g, and 15b are set to be adjusted, for example, to respectively suitable film thickness, transmittance, and hue.

The above-mentioned insulating film 15 is formed by repeatedly performing a procedure by three times in which first, the inter-layer insulating film colored with the respective colors is coated by a predetermined film thickness, and next, a process is carried out to leave only necessary portions through the photolithography method for each of the respective colors.

With the above-mentioned configuration, an outside light h incident from the transparent substrate 65 side in the electrophoretic display device 70a′ passes through the electrophoretic type display section 61 and further passes through the inter-layer insulating films 15r, 15g, and 15b of the respective pixels for the color selection and also is reflected by the shield layer 13a to be taken out again from the transparent substrate 65 side as respective color lights H.

According to this, it is possible to realize the color display in which the shield layer 13a provided characteristically to the present invention is used as the reflection layer.

It should be noted that the above-mentioned configuration is effective in a configuration in which, in particular, the shield layer 13a functioning as the reflection layer in a state of covering the entire surface of the display region is provided but can be also applied to a configuration in which the shield layer described according to the second embodiment (FIGS. 4 and 5) and the third embodiment (FIGS. 6 and 7) is used as the shield layer of the active matrix type the electrophoretic display device.

### Eighteenth Embodiment

According to the present eighteenth embodiment, a description will be given of an example of a control on a shield layer in a display device having a configuration in which the potential at the shield layer can be controlled independently to the respective electrodes and wirings among the display devices according to the above-mentioned respective embodiments.

FIG. 29 shows a flow chart for carrying out such a control. Herein, a procedure of performing a display at a luminance in accordance with an operational environment thought the potential control of the shield layer will be described along the flow chart.

First, in a first step S1, brightness (outside light) in the operational environment of the display device is sensed by the light receiving element to perform photoelectric conversion.

Next, in a second step S2, on the basis of an electrical signal photoelectrically converted by the light receiving element, a potential applied to the shield layer is calculated so that the luminance display suited to the brightness of the operational environment is performed.

After that, in a third step S3, the calculated potential is applied to the shield layer for performing the display.

In order to carry out the above-mentioned control, in the peripheral region of the display device provided with the shield layer according to the present invention, a light receiving element for performing photoelectric conversion in Step 1 and a screen luminance control circuit for performing the processing in Step S2 are set to be provided.

By carrying out the above-mentioned control, as the luminance in accordance with the operational environments (dark and bright) can be obtained, it is possible to perform the display in which the appropriate potential is applied to the shield layer.

It should be noted that according to the above-mentioned respective first to eighteenth embodiments, the configuration in which the present invention is applied to the display device has been described. However, the present invention is not limited to the application to the display device but can be widely applied to a semiconductor device such as a memory or a sensor as long as the wiring and electrodes are provided on the bottom gate type thin film transistor via the insulating film in the configuration.

In the semiconductor device having such a configuration, by arranging the conductive shield layer between the thin film transistor and the electrode while maintaining the insulation property, it is possible to stabilize the operational characteristic of the thin film transistor. Also, as a property fluctuation accompanied by a load operation of the transistor (threshold fluctuation due to bias stress) can be compensated by the potential applied to the shield layer, it is possible to achieve the longer life of the transistor. Furthermore, by using a metal with the good gas barrier property for the shield layer, the gas barrier property of the protection film can be enforced, and it is possible to improve storage life of the transistor.

Also, effects related to these transistors are also the effects similarly obtained with respect to the embodiments of the above-mentioned display device.

1. A semiconductor device comprising a bottom gate type thin film transistor provided on a substrate and an electrode provided on an upper part of the thin film transistor via an insulating film,
characterized in that between the thin film transistor and the electrode, a conductive shield layer is arranged while an insulation property between these is maintained.

2. The semiconductor device according to claim 1, characterized in that
a channel layer of the thin film transistor is composed of an organic semiconductor thin film.

3. The semiconductor device according to claim 1, characterized in that
the shield layer is connected to a gate electrode or a source electrode of the thin film transistor.

4. The semiconductor device according to claim 1, characterized in that
the shield layer is subjected to a potential control independently with respect to the thin film transistor.

5. The semiconductor device according to claim 1, characterized in that
the electrode provided on the upper part of the thin film transistor is connected to the thin film transistor.

6. The semiconductor device according to claim 1, characterized in that
a plurality of the thin film transistors are arranged on the substrate, and
the shield layer is commonly provided in a state of covering the plurality of the thin film transistors.

7. A display device comprising a bottom gate type thin film transistor provided on a substrate and an electrode provided on an upper part of the thin film transistor via an insulating film,
characterized in that between the thin film transistor and the electrode, a shield layer is arranged while an insulation property between these is maintained.

8. The display device according to claim 7, characterized in that
the electrode provided on the upper part of the thin film transistor is a pixel electrode connected to the thin film transistor.

9. The display device according to claim 7, characterized in that
a plurality of the thin film transistors are arranged on the substrate, and
the electrode provided on the upper part of the thin film transistor is a common electrode commonly arranged opposite to the plurality of the thin film transistors.
